(19) United States
(12) Patent Application Publication
(10) Pub. No.: US 2021/0357006 A1
(43) Pub. Date: Nov. 18, 2021

(54) INSTRUMENTATION SYSTEMS WITH EXPANDED CAPABILITIES

(71) Applicant: HILLER MEASUREMENTS, INC., Austin, TX (US)

(72) Inventors: Jeffrey Don OLSEN, Austin, TX (US); Abhay SAMANT, Austin, TX (US); Joseph Michael SANDERS, Austin, TX (US); Hillman Lee BAILEY, Austin, TX (US)

(21) Appl. No.: 17/276,792

(22) PCT Filed: Sep. 16, 2019
(86) PCT No.: PCT/US2019/051347

§ 371 Date: Mar. 16, 2021

Related U.S. Application Data
(60) Provisional application No. 62/732,385, filed on Sep. 17, 2018.

(51) Int. Cl. G06F 1/18; H05K 7/14

(52) U.S. Cl. CPC G06F 1/186; H05K 7/1402; H05K 7/1425

(57) ABSTRACT

An instrumentation system that can include a chassis configured to receive a PCB assembly, where the PCB assembly can include a front edge forming a front plane, a first rear edge forming a first rear plane, and a second rear edge forming a second rear plane, with the first rear plane being spaced a greater distance away from the front plane than the second rear plane, and where the chassis can include a plurality of card slots configured to receive the PCB assembly, a 3U backplane configured to couple with the second rear edge of the card when the PCB assembly is installed in one of the plurality of card slots in the chassis.

### TECHNICAL FIELD

The present disclosure relates generally to instrumentation systems, and, in an embodiment described herein, more particularly provides an instrumentation system with enhanced capabilities over current instrumentation platforms.

### BACKGROUND ART

The current PXI™ Express standards define 3U and 6U size cards for configuring instrumentation systems. The PXI™ Express standard is an upgrade over the VXI standard (VMEbus eXtensions for Instrumentation). The VXI standard based systems are no longer widely supported in the instrumentation industry, which has largely adopted the newer PXI™ Express standard. The VXI system components are incompatible with various PXI™ Express system components, therefore, as these VXI systems age, they may be replaced by PXI™ Express based systems. However, these systems may not provide some of the capabilities of the older VXI systems and thus make the transition away from VXI more cumbersome. One benefit to adopting the PXI™ Express standard for new systems is the availability of commercial-off-the-shelf 3U PXI™ Express function and control cards, which is quite extensive. However, the 6U PXI™ Express cards may not provide adequate support for the needs of the current instrumentation systems. Therefore, the current disclosure provides a unique configuration that can utilize the existing 3U PXI™ Express function and control cards, while also providing an increased integration density over the PXI™ Express standard which is needed to meet the requirements of ever increasing instrumentation system complexities.

A PXI™ Express compliant chassis can accommodate various configurations of custom and/or off-the-shelf system controller cards and peripheral cards to provide desired control and interface of various systems under test. However, as stated above, due to the increasing complexities of systems to be tested, the available real-estate needed for test electronics integration into the PXI™ Express chassis is increasingly challenging. Therefore, it will be readily appreciated that improvements in the arts of instrumentation systems are continually needed.

### BRIEF DESCRIPTION OF THE DRAWINGS

Various embodiments of the present disclosure will be understood more fully from the detailed description given below and from the accompanying drawings of various embodiments of the disclosure. In the drawings, like reference numbers may indicate identical or functionally similar elements. Embodiments are described in detail hereinafter with reference to the accompanying figures, in which:

FIG. 1 is a representative side view of a 3U PXI™ Express System slot card and backplane connectors;

FIG. 2 is a representative side view of a 6U PXI™ Express System slot card and backplane connectors;

FIG. 3 is a representative table of current and voltage requirements for PXI™ Express card slots;

FIG. 4 is a representative perspective view of a P-XLe (i.e. Extra Large PXI) instrumentation system chassis, according to one or more example embodiments;

FIG. 5 is a representative front view of a P-XLe instrumentation system chassis, according to one or more example embodiments;

FIG. 6 is a representative rear view of a P-XLe instrumentation system chassis, according to one or more example embodiments;

FIG. 7 is another representative perspective view of a P-XLe instrumentation system chassis, according to one or more example embodiments;

FIG. 8 is cut-away perspective view of a P-XLe instrumentation system chassis, according to one or more example embodiments;

FIG. 9A is a representative side view of a 6U P-XLe System card, according to one or more example embodiments; and

FIG. 9B is a representative side view of a 6U P-XLe System card with an expansion PCB, according to one or more example embodiments;

FIG. 9C is a representative side view of a 6U P-XLe System card that includes separate PCBs for the 3U PXI region and the 6U P-XLe region, according to one or more example embodiments;

FIG. 9D is a representative side view of a 6U P-XLe System card that includes separate PCBs for the 3U PXI region and the 6U P-XLe region, and an expansion PCB, according to one or more example embodiments;

FIG. 9E is a representative side view of a 6U P-XLe System card with the 3U PXI region justified to the rear of the card, according to one or more example embodiments;

FIG. 9F is a representative side view of a 6U P-XLe System card that includes separate PCBs for the 3U PXI region and the 6U P-XLe region, with the 3U PXI region PCB justified to the rear of the card, according to one or more example embodiments;

FIG. 9G is a representative side view of a 6U P-XLe System card that includes separate PCBs for the 3U PXI region, the 6U P-XLe region, and an extension region, according to one or more example embodiments; and

FIGS. 10-12 are representative cross-sectional side views of P-XLe instrumentation system chassis with various air flow configurations, according to one or more example embodiments.

### SUMMARY

In accordance with an aspect of the disclosure, a printed circuit board (PCB) assembly that can include a first region with a first height L5, a front edge defining a front plane, and a first rear edge defining a first rear plane, and a second region with a second height L6, the front plane including a front edge of the second region, and a second rear edge defining a second rear plane, wherein the first rear plane and the second rear plane are parallel to each other and are spaced apart from each other. The PCB assembly can further include a first length L1 between the front plane and the first rear plane, a second length L2 between the front plane and the second rear plane, with the first length L1 being greater than the second length L2.

In accordance with another aspect of the disclosure, an instrumentation system for configurable test solutions that can include a chassis configured to receive a first card, with the first card being a printed circuit board (PCB) assembly, where the first card can include a front edge forming a front plane, a first rear edge forming a first rear plane, and a second rear edge forming a second rear plane, with the first rear plane being spaced a greater distance away from the front plane than the second rear plane, and where the chassis can include a plurality of card slots configured to receive the first card, a 3U backplane configured to couple with the second rear edge of the card when the first card is installed in one of the plurality of card slots in the chassis.

### DETAILED DESCRIPTION OF THE PREFERRED EMBODIMENT(S)

Present embodiments provide a configurable instrumentation system for cooling and powering multiple printed circuit board (PCB) assemblies that can be interconnected within the configurable instrumentation system to support test control and data collection operations for one or more devices under test (DUTs) or systems under test (SUTs). An individual chassis can provide configurable components to accept custom or standard PCBs, provide power to these PCBs, provide sufficient cooling of the PCBs, provide configurable external Input/Output (I/O) connections, provide configurable internal I/O connections within the chassis, and provide local and distributed control systems to control test operations. Multiple of these chasses can be interconnected together to provide increased operational capabilities to meet the testing needs of the DUTs or SUTs.

As used herein, the terms “comprises,” “comprising,” “includes,” “including,” “has,” “having,” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

The use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise.

The use of the word “about”, “approximately”, or “substantially” is intended to mean that a value of a parameter is close to a stated value or position. However, minor differences may prevent the values or positions from being exactly as stated. Thus, differences of up to ten percent (10%) for the value are reasonable differences from the ideal goal of exactly as described. A significant difference can be when the difference is greater than ten percent (10%).

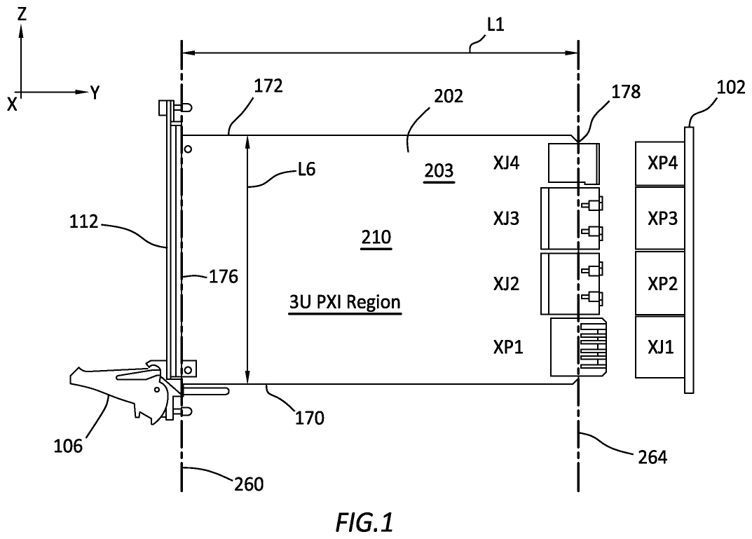

FIGS. 1-3 show various standard requirements for a PXI™ Express system as provided in the specification entitled: “PXI™-5, PXI™ Express Hardware Specification, PCI EXPRESS eXtensions for Instrumentation, An Implementation of CompactPCI™ Express Rev. 1.0 8/22/2005” This specification is incorporated herein by reference in its entirety. If there are any conflicts or inconsistencies between the PXI™ Express Hardware Specification and this present disclosure, this present disclosure will take precedence. For example, the 6U P-XLe card (which can also be referred to as a 6U P-XL card) of this present disclosure can be different than the 6U PXI™ Express card defined in the PXI™ Express Hardware Specification. Also the power available per card slot in the PXI™ Express Hardware Specification may differ from this disclosure. For example, each card slot in the P-XLe instrumentation chassis can supply more power to P-XLe cards than is available to cards in a PXI™ Express compliant system.

FIG. 1 is a representative side view of a 3U PXI™ Express System slot card and backplane connectors. These are representative of a 3U card 202 (that includes a PCB 203) and a 3U backplane 102 for a system card slot in a 3U PXI™ Express System. However, various other connectors can be used as provided in the PXI™ Express Hardware Specification, such as for peripheral cards slots, expansion slots, etc. Also, input/output (I/O) connectors can extend from the card through the front panel 112 for external I/O connectivity to the 3U card 202. The connectors described in this disclosure can transfer various types of information, including power signals, external signals (such as sensor data and event control), and internal signals, such as data and control signals (e.g. communication via the 3U PXI™ backplane 102). The lower extraction mechanism 106 can be used to assist in removal of the card 202 from the chassis and the 3U backplane 102. It is not required for the mechanism 106 to also assist in the insertion of the 3U card 202 into the chassis and mating to the 3U backplane 102, but it can be configured to do so if desired.

Specific I/O connectors XP1 and XJ2-4 are described in the PXI™ Express Hardware Specification for a 3U system slot. These connectors can mate to respective backplane connectors XJ1 and XP2-4 when the 3U card 202 is inserted in the chassis. It should be understood that several other connector configurations are allowed in the 3U chassis configuration. FIG. 1 merely shows one possible configuration of connectors. If this card 202 was to be installed in a 3U system card slot, then the top edge 172 of the card 202 can engage an upper card guide in the 3U system card slot to guide the 3U card 202 to the 3U backplane 102 and align the 3U card 202 connectors with the 3U backplane connectors. The bottom edge 170 of the card 202 can engage a lower card guide in the 3U system card slot to guide the card 202 (in cooperation with upper card guide) to the 3U backplane and align the 3U card connectors with the 3U backplane connectors. The 3U card 202 includes a 3U PXI region 210 that can contain circuitry needed to perform the 3U PXI card functions including interface with the 3U PXI backplane 102 as well as the optional I/O connectors that can extend through the front panel 112. The 3U PXI region 210 can be a height L6 from the bottom edge 170 to the top edge 172.

The front edge 176 of the 3U PCB 203 can define a front X-Z plane 260, and rear edge 178 of the 3U PCB 203 can define a rear X-Z plane 264. The front panel 112 of the 3U card 202 can be parallel to the front X-Z plane 260, but spaced away from the front plane 260. The front X-Z plane 260 is defined by the points of the 3U PCB 203 that are farthest away from the rear edge 178 of the 3U PCB 203. Therefore, notches at the front edge of the 3U PCB 203 (such as for installing connectors along the front edge 176) may tend to meander the front edge profile. However, the front X-Z plane 260 is defined by the points of the 3U PCB 203 that are farthest away from the rear edge 178 of the 3U PCB 203 (or farthest away from the rear X-Z plane 264).

Similarly, the rear X-Z plane 264 is defined by the points of the 3U PCB 203 that are farthest away from the front edge of the 3U PCB 203. Therefore, notches at the rear edge of the 3U PCB 203 for installing connectors along the rear edge may tend to meander the rear edge profile, but the rear X-Z plane 264 is defined by the points of the 3U PCB 203 that are farthest away from the front edge 176 (or farthest away from the front X-Z plane 260). The length L1 indicates a distance between the front X-Z plane and the rear X-Z plane. Therefore, the area of the 3U PXI region can be determined by multiplying L1 times L6.

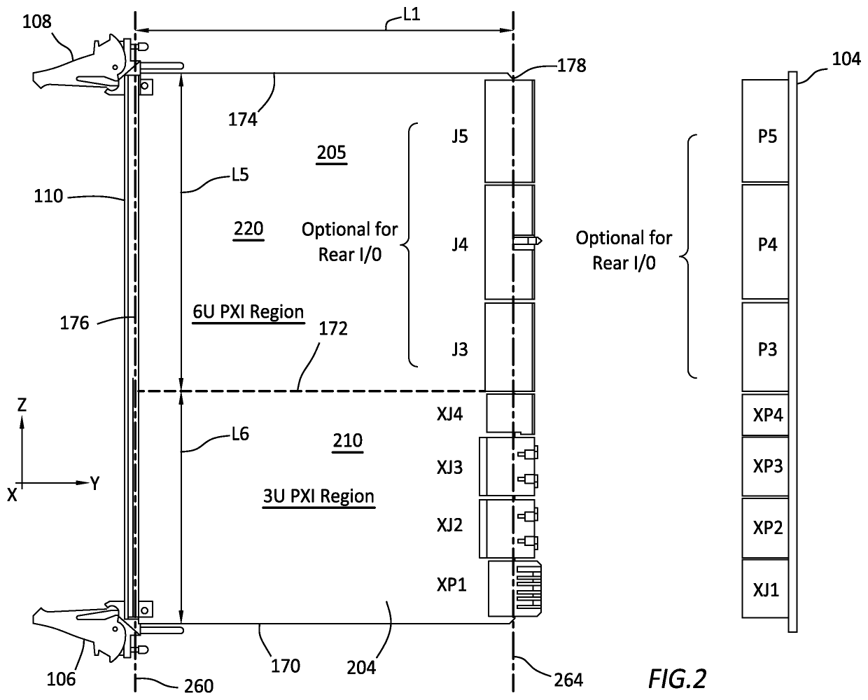

FIG. 2 is a representative side view of a 6U PXI™ Express System slot card and backplane connectors. These are representative of a 6U card 204 (that includes a PCB 205) and a 6U backplane 104 for a system card slot in a 6U PXI™ Express System. However, various other connectors can be used as provided in the PXI™ Express Hardware Specification, such as for peripheral cards slots, expansion slots, etc. Also, input/output (I/O) connectors can extend from the card through the front panel 110 for external I/O connectivity to the 6U card 204. The upper and lower extraction mechanisms 108, 106 can be used to assist in removal of the 6U card 204 from the 6U chassis and the 6U backplane 104. It is not required for the mechanisms 108, 106 to also assist in the insertion of the card 204 into the 6U chassis and mating to the backplane 104, but they can be configured to do so if desired.

Specific I/O connectors XP1, XJ2-4 (as described above for the 3U PXI™ region) and J3-J5 are shown and these relate to these same designated connectors given in the PXI™ Express Hardware Specification for a 6U system slot. These connectors can mate to respective backplane connectors XJ1, XP2-4, and P3-P5 when the 6U card 204 is inserted in the 6U chassis and when these optional connectors are used. It should be understood that several other connector configurations are allowed in this 6U chassis configuration. FIG. 2 merely shows one possible configuration of connectors. If this card 204 is installed in a 6U PXI chassis slot, then the top edge 174 of the card 204 can engage an upper card guide in the 6U PXI chassis to guide the card 204 to the backplane 104 and align the card 204 connectors with the backplane connectors. The bottom edge 170 of the card 204 can engage a lower card guide in the 6U PXI chassis to guide the card 204 (in cooperation with upper card guide) to the backplane and align the card connectors with the backplane connectors. The card 204 includes a 3U PXI region 210 and 6U PXI region 220. The 3U PXI region 210 can contain circuitry needed to perform the 3U PXI card functions including interface with the 3U PXI portion of the 6U PXI backplane 104, as well as with the optional I/O connectors that can extend through the front panel 110. The 6U PXI region 220 can contain circuitry needed to perform the 6U PXI card functions including interface with the 6U PXI portion of the 6U PXI backplane 104, as well as with the optional I/O connectors that can extend through the front panel 110. It should be noted that this 6U PXI region 220 is expanded in the present disclosure to provide more capabilities for a 6U system. This will be described in more detail below.

The front edge 176 of the 6U PCB 205 can define a front X-Z plane 260, and rear edge 178 of the 6U PCB 205 can define a rear X-Z plane 264. The front panel 112 can be parallel to the front X-Z plane 260, but spaced away from the front plane 260. The front X-Z plane 260 is defined by the points of the 6U PCB 205 that are farthest away from the rear edge 178 of the 6U PCB 205. Therefore, notches at the front edge 176 of the 6U PCB 205 for installing connectors along the front edge 176 may tend to meander the front edge profile, but the front X-Z plane 260 is defined by the points of the 6U PCB 205 that are farthest away from the rear edge 178 of the 6U PCB 205 (or farthest away from the rear X-Z plane 264).

Similarly, the rear X-Z plane 264 is defined by the points of the 6U PCB 205 that are farthest away from the front edge 176 of the 6U PCB 205. Therefore, notches at the rear edge 178 of the 6U PCB 205 for installing connectors along the rear edge 178 may tend to meander the rear edge profile, but the rear X-Z plane 264 is defined by the points of the 6U PCB 205 that are farthest away from the front edge 176 of the 6U PCB 205 (or farthest away from the front X-Z plane 260).

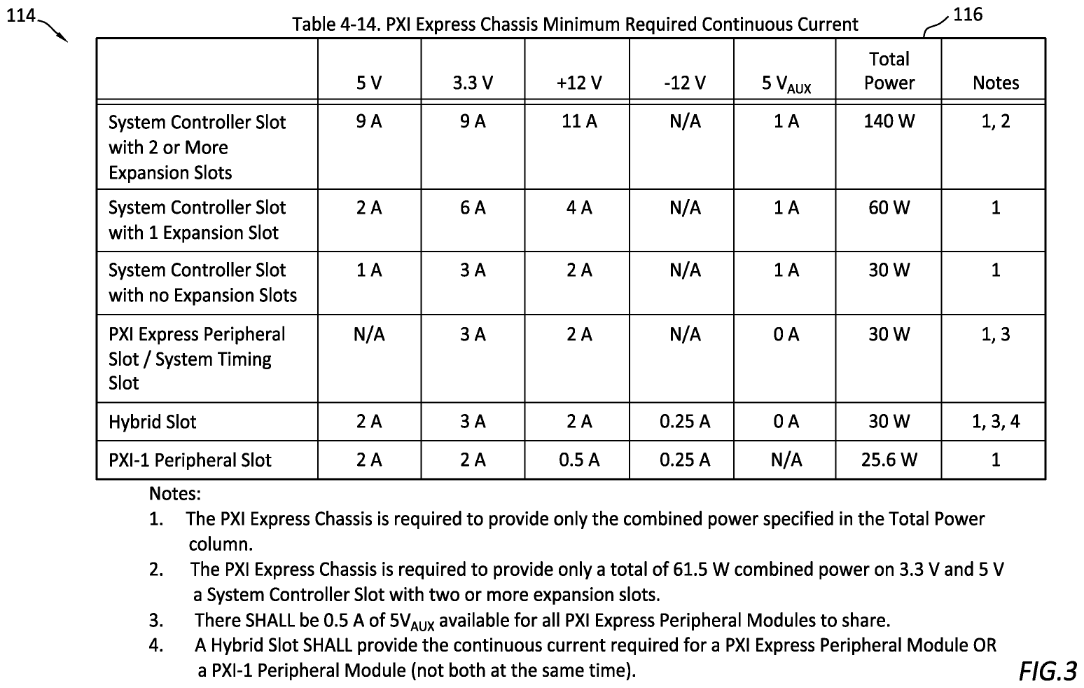

FIG. 3 is a representative table 114 of minimum required currents and voltages for PXI™ Express card slots. The currents for specific voltages are given as well as minimum power requirements for PXI™ Express card slots. The present disclosure provides additional power for the P-XLe card slots in a P-XLe system chassis. Therefore, the total power column 116 is not necessarily applicable to the P-XLe system chassis, since the card slots for the P-XLe system chassis can supply more power per card slot (i.e. increased amounts of current can be available for various voltages for each card slot). This demonstrates some of the added capabilities of the P-XLe system chassis over a PXI™ Express system chassis.

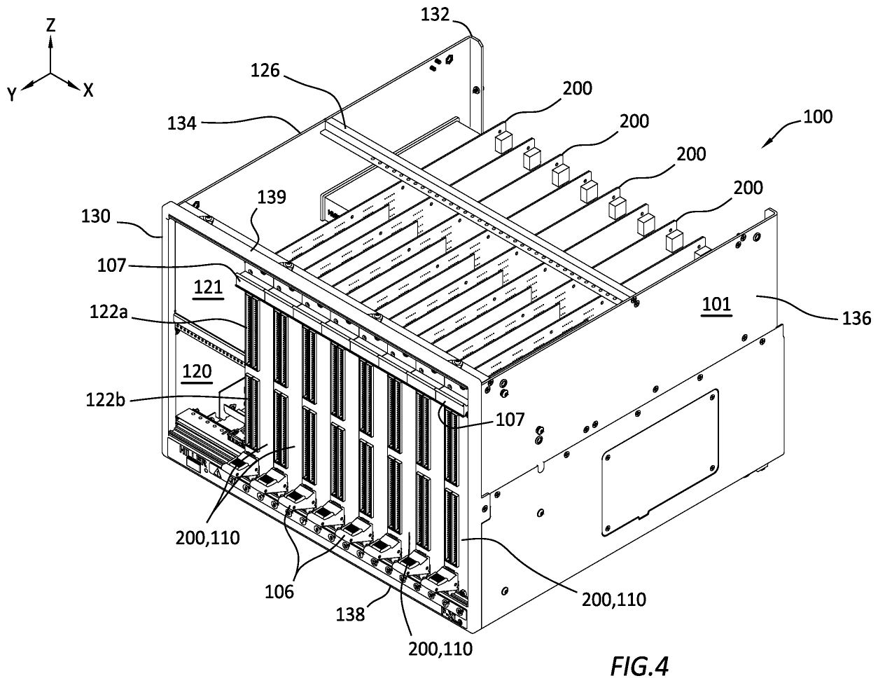

FIG. 4 is a representative perspective view of a chassis (or card cage) 101 of a P-XLe (i.e. eXtra Large PXI) instrumentation system 100, according to one or more example embodiments. This P-XLe chassis 101 example can include up to 8 double-width P-XLe card assemblies 200 (as shown in FIG. 4) or up to 16 single-width P-XLe card assemblies (not shown), and any combinations thereof, as long as the total number of slots used for the P-XLe cards does not exceed 16, at least in this configuration. More or fewer P-XLe card slots can be provided in other configurations of the P-XLe system chassis 101. The system controller expansion slots 120 allow for various configurations of system controller cards for the example P-XLe instrumentation system 100. It may be preferred to use one or more off-the-shelf 3U PXI™ controllers in the controller expansion slots 120, but other custom controller cards can also be used.

The area 121 indicated in the front 130 of the chassis 101 can be used for power supply expansion, cooling system expansion, additional custom printed circuit cards for specialized implementations of the P-XLe system, or combinations thereof, or left empty as desired. If custom cards are to be installed in the area 121, then an optional backplane can be installed in the chassis 101 to provide connection between the custom cards, between the custom cards and the P-XLe cards, or between external interfaces, such as special test equipment, systems under test, etc.

The chassis 101 can include a front 130, a rear 132, a left side 134, a right side 136, a bottom 138, and a top 139. A card guide support 126 can be used to secure top card guides near the top of the card age 101, which can provide guidance and retention of P-XLe cards 200 as they are installed in the chassis 101. As can be seen, the cards 200 can extend to proximate the rear 132 of the chassis 101. It should be understood that the configuration of eight double-wide P-XLe card 200 shown in these figures (including FIGS. 4-7) is only one example configuration of a P-XLe instrumentation system 100. Various arrangements of single-wide and double-wide cards 200 can be installed in the chassis 101 in keeping with the principles of this disclosure.

The cards 200 can include extraction mechanisms 108, 106 as shown in FIG. 2. However, the example cards in FIG. 4 include only the lower extraction mechanism 106, with a label portion 107 positioned proximate the top of the front panel 110, were the other mechanism 108 can be positioned, if desired. The label portion 107 can include a rigid structure that assists a user in gripping the card 200 when installing or extracting the card 200. The label 107 may also be used to provide a visual identification of the card 200 to which it is attached.

Optional front I/O connectors 122a, 122b on each card 200 can provide interfaces between the card 200 and external equipment being monitored and/or controlled by the P-XLe instrumentation system 100. These connectors 122a, 122b can include connectors for transmitting various types of signals (e.g. single-ended signals, twisted pair signals, controlled impedance signals transmitted over coax, optical waveguides, optical signals, etc.).

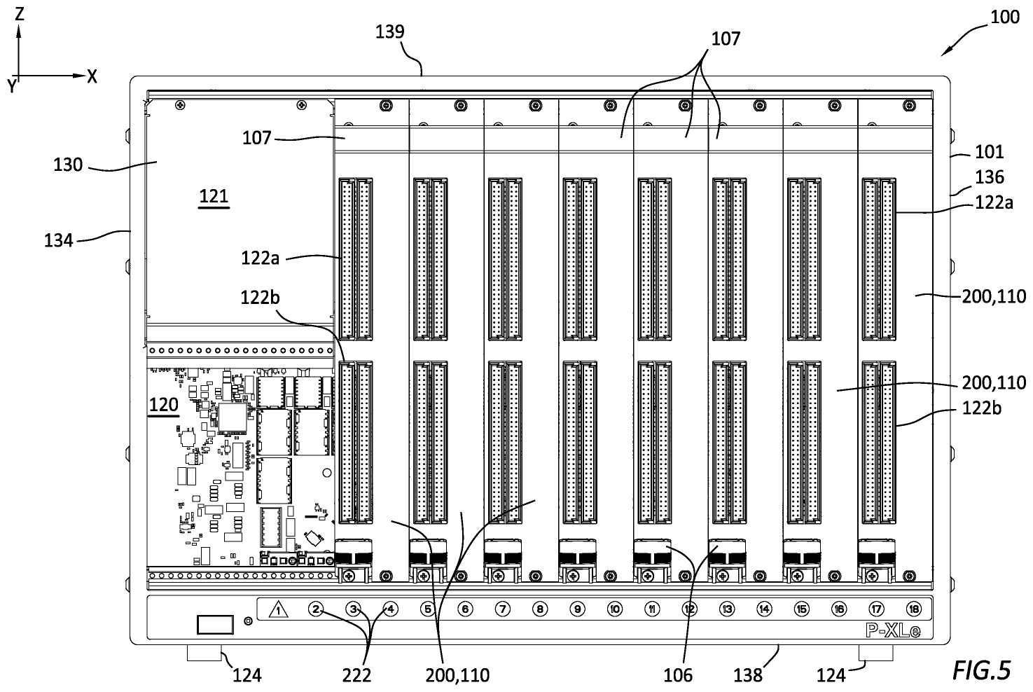

FIG. 5 is a representative front view of a P-XLe instrumentation system 100 chassis 101, according to one or more example embodiments. The system 100 in FIG. 5 is representative of a front view of the system 100 shown in FIG. 4. The chassis 101 has a front 130, a left side 134, a right side 136, a bottom 138 and a top 139. The controller expansion 120 is shown without a 3U controller installed, but this area is where one or more of the 3U PXI™ controllers can be installed. As stated above, the area 121 can be variously configured with custom cards and/or other expansion capabilities. It should be understood, that 3U PXI™ controllers can be also be installed in the lower portion of each of the P-XLe card slots when a P-XLe card 200 is not installed in the slot. The label 107 can be used to identify each card 200 with various kinds of markings that can indicate the card's identity. Optional front I/O connectors 122a, 122b on each card 200 can provide interfaces between the card 200 and external equipment being monitored and/or controlled by the P-XLe instrumentation system 100. The front I/O connectors 122a, 122b can also provide interfaces for external equipment to monitor and/or control the P-XLe instrumentation system 100.

Optional feet 124 can be installed when the chassis 101 is a stand-alone chassis and positioned on a support surface. However, the feet 124 may not be needed if the chassis 101 is to be rack-mounted with attachment means mounted to the left and right sides 134, 136 of the chassis 101. Slot indicators 222 can be used to indicate which card slot in the chassis 101 a card 200 is installed. These slot indicators 222 can be used to record the location of each card 200 as well as other cards (i.e. 3U controller cards) in the system even when the system includes one or more chassis 101.

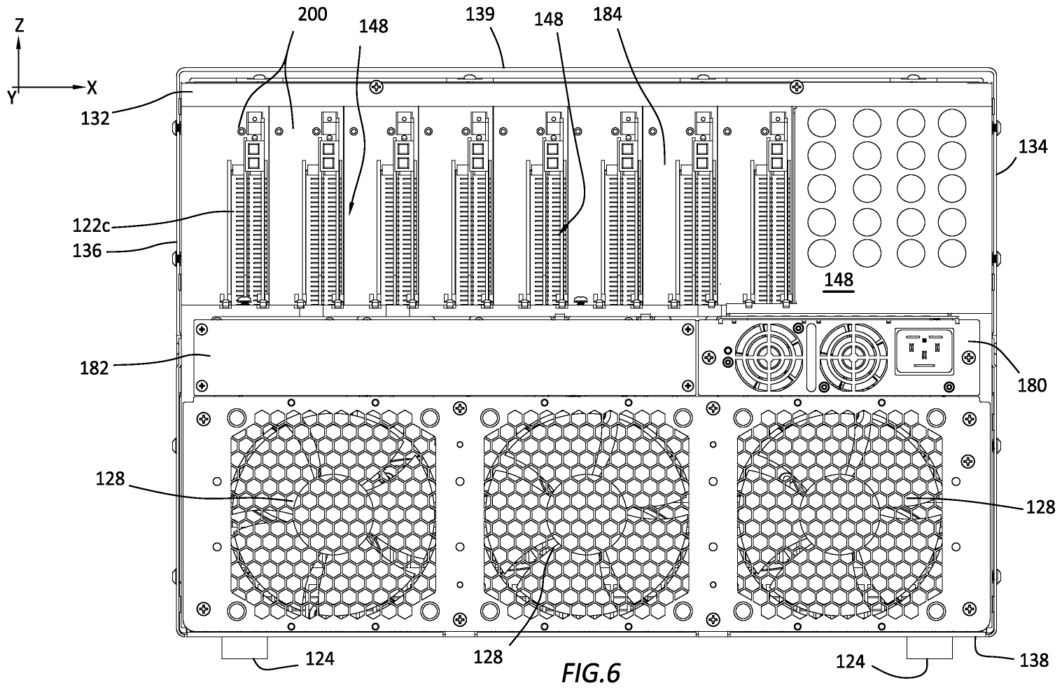

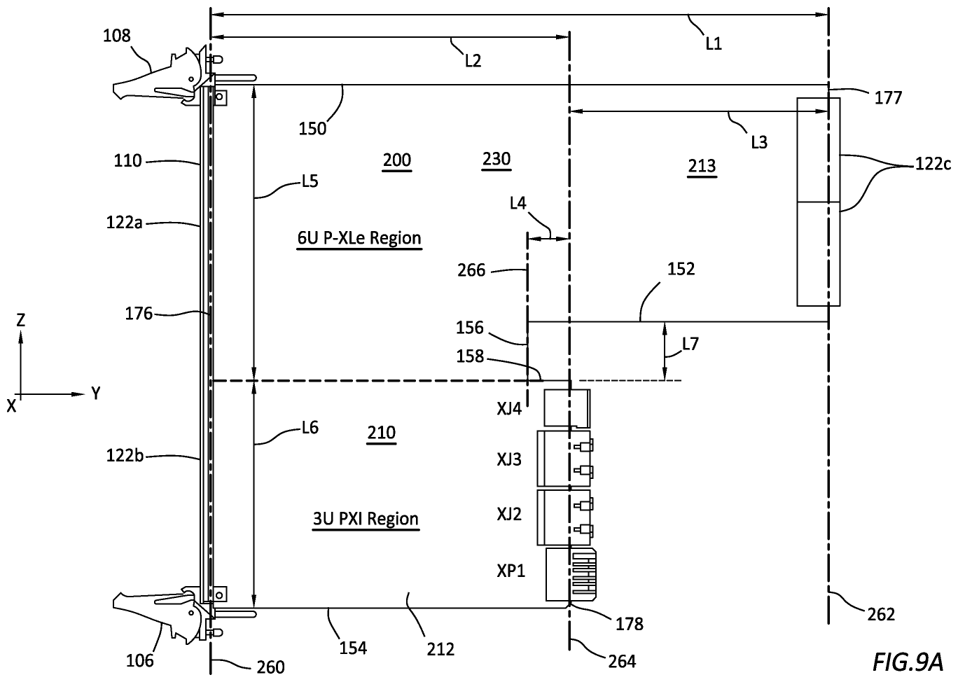

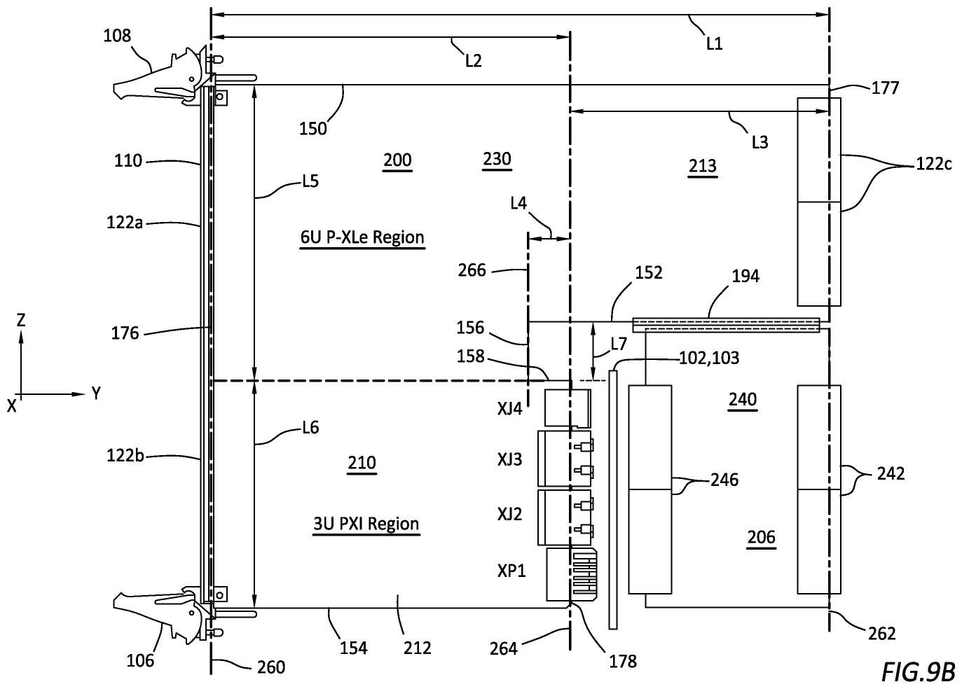

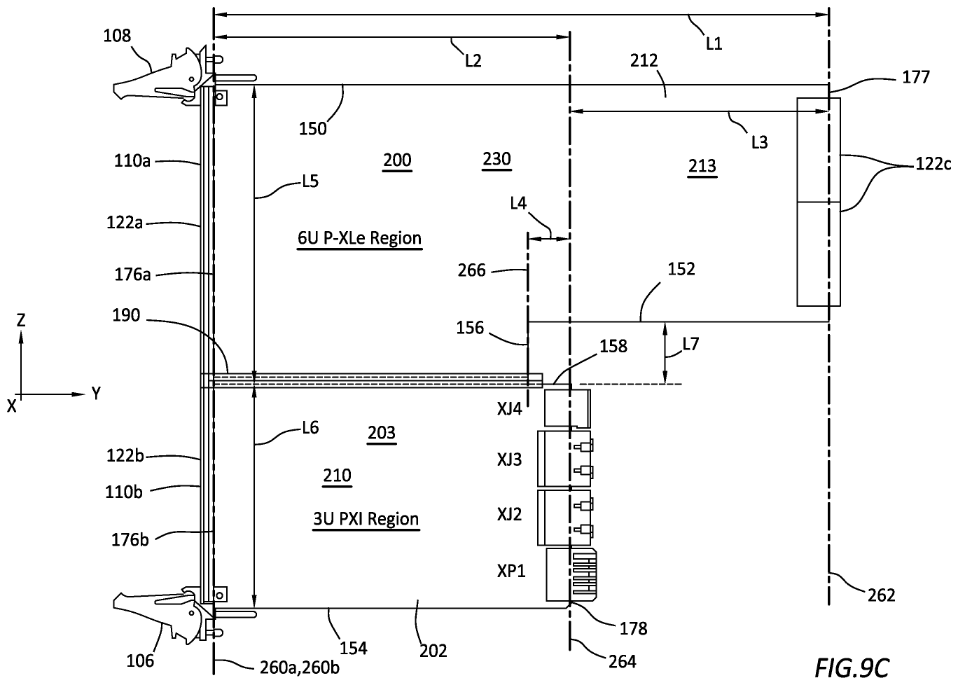

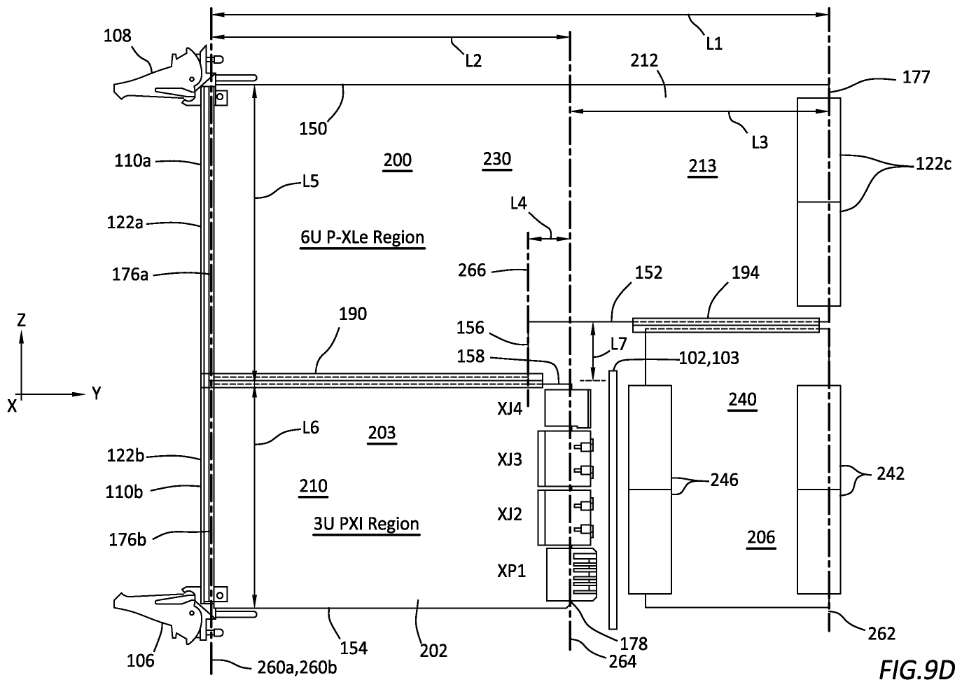

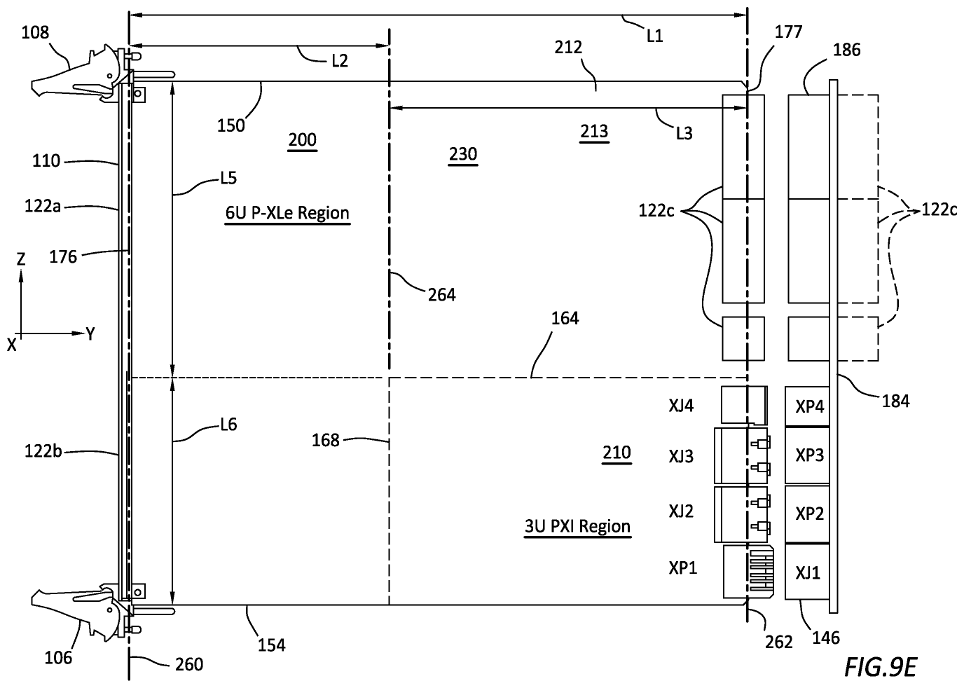

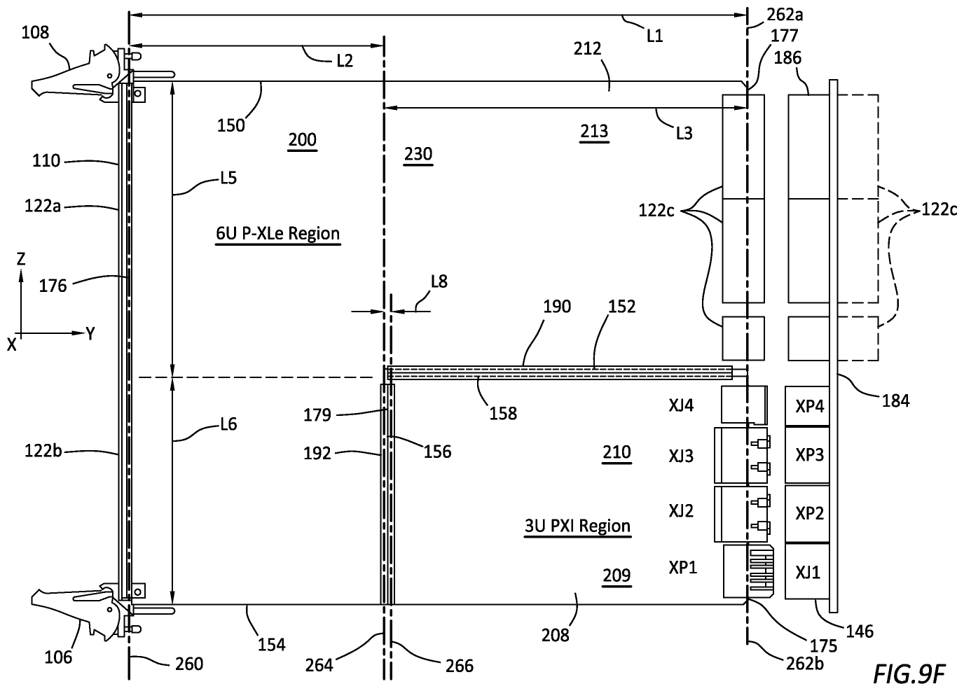

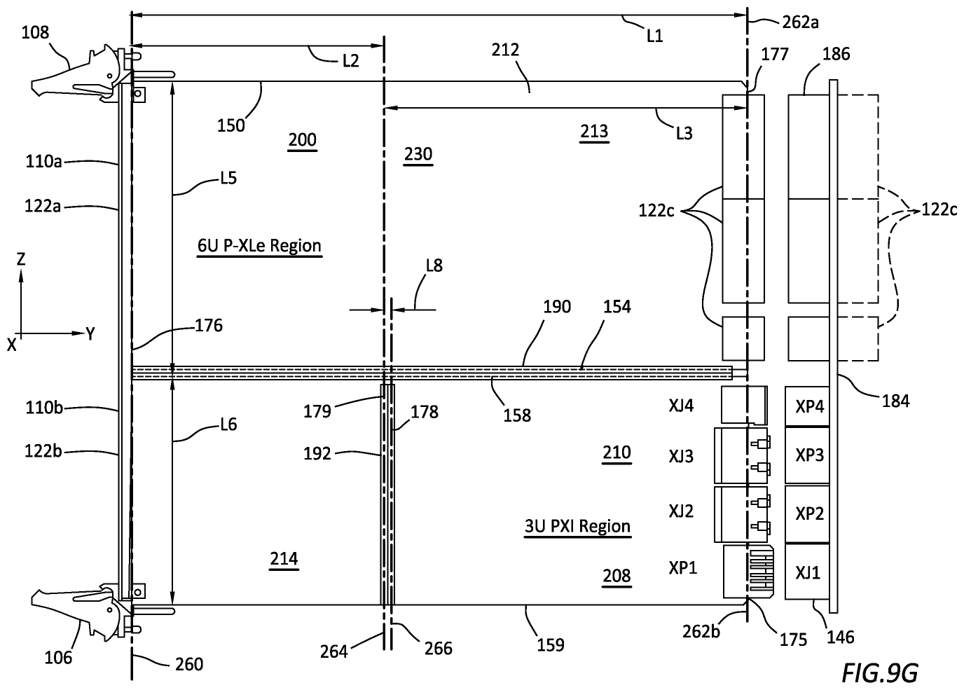

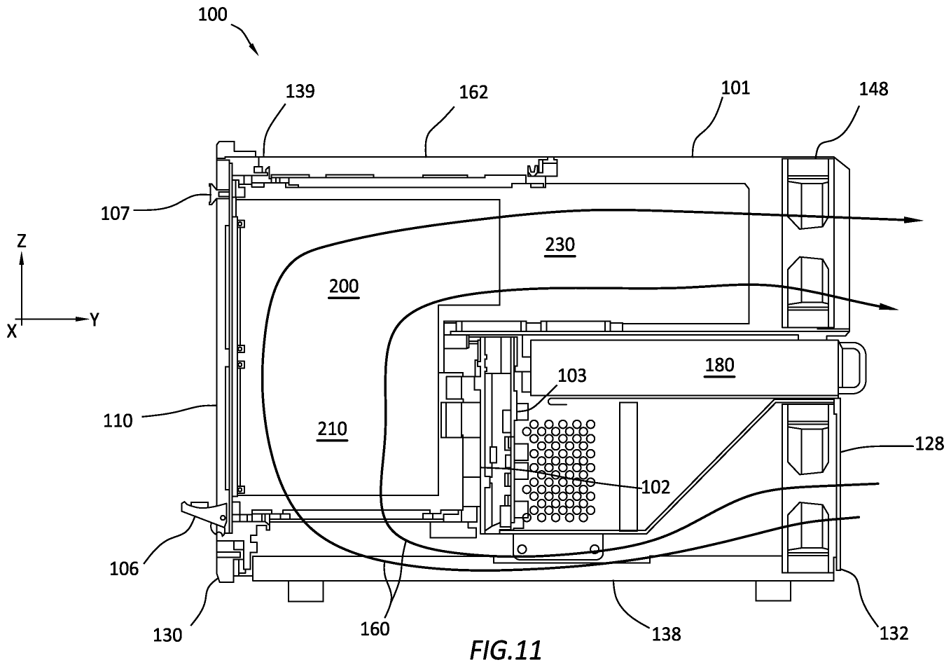

FIG. 6 is a representative rear view of a P-XLe instrumentation system 100 chassis 101, according to one or more example embodiments. The system 100 in FIG. 6 is representative of a rear view of the system 100 shown in FIG. 4. The chassis 101 has a rear 132, a left side 134, a right side 136, a bottom 138 and a top 139. In this example, one or more power supplies 180 can be installed to provide power to the system 100. The expansion area 182 can be used to install additional power supplies 180, such as for redundant power systems. Also, the rear edge of the card 200 can be used for additional system connectivity. Optional rear I/O connectors 122c can be installed at the rear edge 177 (see FIG. 9A) of each card 200 to provide interfaces between the card 200 and external equipment as well as allowing signals transferred between two or more cards 200. Alternatively, or in addition to, a P-XLe backplane 184 can be installed in the chassis 101 at a recessed position from the rear 132 where connectors on the rear edge 177 of one or more of the cards 200 can connect to the P-XLe backplane 184 for enhanced signal and power distribution between the cards 200 as well as enhanced connectivity for connecting to external equipment. Therefore, the connectors 122c can be connectors on the P-XLe backplane 184 or connectors attached directly at the rear edge 177 of the card 200. These connectors 122c can include a plurality of connectors as well as various types of connectors for transmitting various types of signals (e.g. single-ended signals, twisted pair signals, controlled impedance signals transmitted over coax, optical waveguides, optical signals, etc.). One or more fans 128 can be installed in the chassis 101 as shown with the perforated areas in the rear 132 of the chassis 101 providing EMI shielding as well as an air inlet to the fans 128. One or more optional exhaust fans 148 can be installed in the chassis 101 at positions indicated by the reference numerals 148, but are not shown. If the exhaust fans 148 are installed, then the perforated areas in the rear 132 of the chassis 101 may also be used to provide EMI shielding as well as an air exhaust from the chassis 101 for the upper portion of the rear of the chassis 101. The position of one or more optional exhaust fans 148 are shown more clearly in FIG. 11. Optional feet 124 can be installed when the chassis 101 is a stand-alone chassis and positioned on a support surface. However, the feet 124 may not be needed if the chassis 101 is to be rack-mounted with attachment means mounted to the left and right sides 134, 136 of the chassis 101.

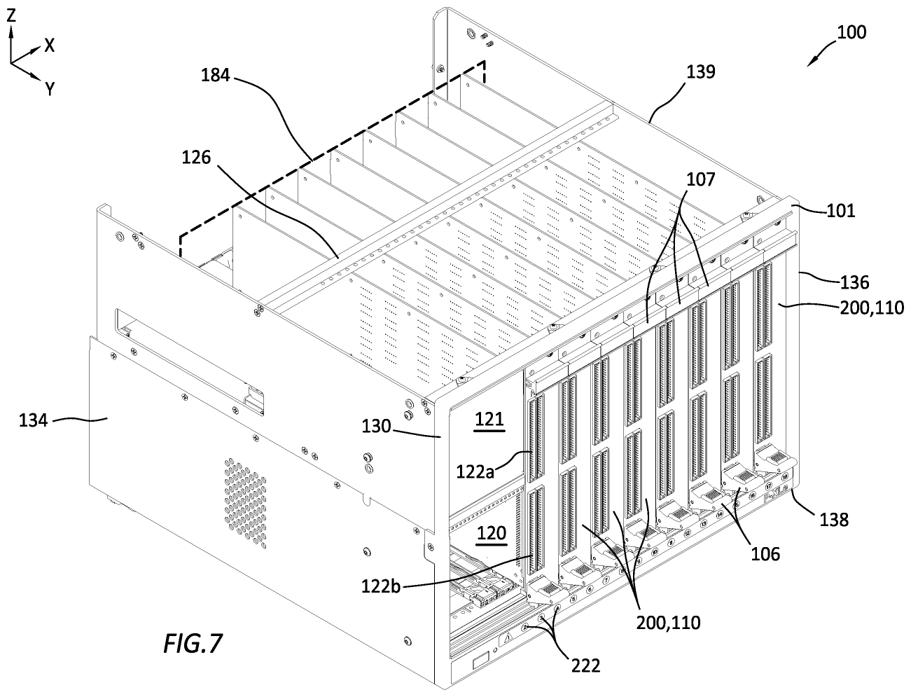

FIG. 7 is another representative perspective view of a P-XLe instrumentation system chassis 101, according to one or more example embodiments. The system 100 in FIG. 7 is a representative perspective view of the system 100 shown in FIG. 4 but at a different perspective. The chassis 101 has a front 130, a left side 134, a right side 136, a bottom 138 and a top 139. The controller expansion 120 is shown without a 3U controller installed, but this area is where one or more of the 3U PXI™ controllers can be installed. As stated above, the area 121 can be used for power supply expansion, cooling system expansion, additional custom printed circuit cards for specialized implementations of the P-XLe system, or combinations thereof, or left empty as desired. If custom cards are to be installed in the area 121, then an optional backplane can be installed in the chassis 101 to provide connection between the custom cards, between the custom cards and the P-XLe cards, or between external interfaces, such as special test equipment, systems under test, etc.

The label 107 can be used to identify each card 200 with various kinds of markings that can indicate the card's identity. Optional front I/O connectors 122a, 122b on each card 200 extending through the front panel 110 can provide interfaces between the card 200 and external equipment being monitored and/or controlled by the P-XLe instrumentation system 100. These connectors 122a, 122b can include connectors for transmitting various types of signals (e.g. single-ended signals, twisted pair signals, controlled impedance signals transmitted over coax, optical waveguides, optical signals, etc.). Slot indicators 222 can be used to indicate which card slot in the chassis 101 a card 200 is installed. These slot indicators 222 can be used to record the location of each card 200 as well as other cards (i.e. 3U controller cards) in the system when the system includes one or more chassis 101. The chassis 101 is shown without an optional P-XLe backplane 184 installed, but a possible location is indicated by the dashed lines.

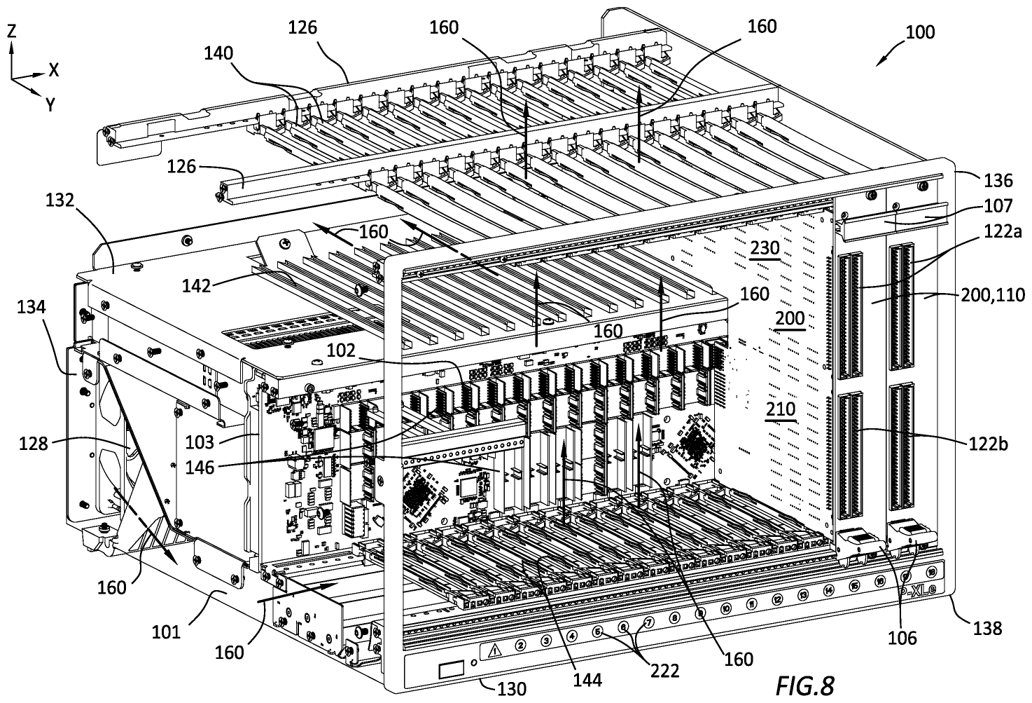

FIG. 8 is cut-away perspective view of a P-XLe instrumentation system chassis 101, according to one or more example embodiments. The chassis 101 includes a front 130, a rear 132, a left side 134, a right side 136, a bottom 138, and a top 139 (top not shown). The cards 200 can be installed through the front 130 of the chassis 101 to engage connectors of a lower portion (the 3U PXI region 210) of each card 200 with connectors of the 3U PXI™ compliant backplane 102. The P-XLe cards 200 can be somewhat “L-shaped” with the upper portion (the 6U P-XLe region 230) extending past the backplane 102 toward the rear 132 of the chassis 101. A notch in the rear of each card 200 can provide clearance for the chassis structure that supports the backplane 102. The top edge 150 of each card 200 can loosely engage a card guide 140 attached to the guide support 126. The bottom edge 154 of each card 200 can loosely engage bottom card guides 144. These guides 140, 144 can guide a card 200 along the desired card slot and align connectors with connectors 146 on the backplane 102. The bottom edge of the 6U P-XLe region 230 of the card 200 can loosely engage intermediate card guides 142. These guides 140, 142 can guide 6U P-XLe region 230 of a card 200 along the desired card slot and align connectors 122c with connectors on the P-XLe backplane 184 (if used). These card guides 140, 142 provide spacing for double-wide cards 200, but additional card guides 140, 142 can be installed to accommodate single-wide cards 200. A power supply backplane 103 can be used to distribute power within the chassis 101, with one or more power supplies 180 electrically connected to the backplane 103.

Air flow 160 can be drawn into the chassis 101 via one or more fans 128 from the rear 132 of the chassis 101. A plenum can be formed in the chassis 101 to direct the air flow as shown by the arrows 160. The amount of air flow 160 forced through the chassis 101 to cool the system 100 components can depend upon the fans 128 selected, the inlet temperature of the air entering the chassis 101, resistance to flow through the chassis 101, as well as many other factors. Alternatively, or in addition to, optional exhaust fans can be used to pull the air out the top rear of the chassis as indicated by the top horizontal (Y-direction) arrows 160. Alternatively, or in addition to, external fans (not shown) can be used to assist air flow 160 through the chassis 101. For example, a 1U high chassis with multiple horizontally mounted fans can be installed above and/or below the chassis 101 in an equipment rack installation. Using the 1U high fan assemblies, the air flow 160 can enter through the bottom of the chassis 101 and exit through the top. Alternatively, or in addition to, a heat exchanger can be used to extract heat from the air prior to the air entering the chassis 101.

The chassis 101 and its support equipment (e.g. fans, power supply, air flow paths, etc.) can support cards 200 with up to 400 watts power dissipation within the chassis. Each card slot can support cards 200 with a total power that is at least 10%, or at least 20%, or at least 30%, or at least 40%, or at least 50%, or at least 60%, or at least 70%, or at least 80%, or at least 90%, or at least 100%, or at least 110%, or at least 120%, or at least 130%, or at least 140%, or at least 150%, or at least 160%, or at least 170%, or at least 180%, or at least 190%, or at least 200%, or at least 210%, or at least 220%, or at least 230%, or at least 240%, or at least 250%, or at least 260%, or at least 270%, or at least 280% greater than total power per card slot for a 6U PXI™ Express chassis, which is 140 watts.

The 6U P-XLe Instrumentation system with chassis 101 can be used to replace VXI-based 6U systems without requiring additional rack height in an equipment rack installation. However, the 6U P-XLe Instrumentation system can provide increased electronics integration in the same rack space of an equipment rack, while utilizing available 3U PXI™ Express products.

FIGS. 9A-9F are representative configurations of the 6U P-XLe card 200 that can be utilized in various configurations of the 6U-P-XLe instrumentation system chassis. Some of the card 200 configurations can interface with expansion cards and backplane connections in the same Y-Z plane of the card 200 in the chassis 101.

FIG. 9A is a representative side view of a 6U P-XLe System card 200, according to one or more example embodiments. The card 200 can include a front panel 110 with optional connectors 122a, 122b (not shown) that can extend through the front panel 110. One or both of the extraction mechanisms 108, 106 can be used to assist an operator in removing and/or inserting the card 200 into the chassis 101. The P-XLe card 200 can include a top edge 150 that can engage the top card guides 140 when the card is installed in the chassis 101. The P-XLe card 200 can include a front portion with a bottom edge 154 that can engage the bottom card guides 144 when the card is installed in the chassis 101. The P-XLe card 200 can include a rear portion with a bottom edge 152 that can engage the intermediate card guides 142 (FIG. 8) when the card is installed in the chassis 101. A notch 156 can be formed in the card 200 to provide clearance from structures in the chassis 101 that may be used to support the backplane 102. The 6U P-XLe region 230 contains circuitry in addition to the circuitry contained in the 3U PXI region 210. The 3U PXI region 210 can contain circuitry that complies with the 3U PXI™ standards as well as additional circuitry if needed. This 3U PXI™ compliant circuitry can be contained wholly within the 3U PXI region 210 or partially contained in the 6U P-XLe region 230 and partially contained in the 3U PXI region 210. It is not a requirement that the 3U PXI™ compliant circuitry be contained only within the 3U PXI region 210, even though it may be desirable to do so.

The standard 3U connectors that mate with the backplane 102 connectors 146 when the card 200 is installed in the chassis 101 can be contained within the 3U PXI region 210 to interface with the backplane 102. Optional I/O connectors 122c can be installed on edge 177 of the card 200. These connectors 122c can plug into an optional backplane 184 or they can connect directly to external connections, without the backplane 184 being installed. These optional I/O connectors 122c may not be installed at all, depending upon the I/O requirements of the system 100.

The P-XLe card 200 can be a card assembly 212 that can include a PCB 213. The PCB 213 can be seen as the foundational structure onto which remaining components of the card assembly 212 (e.g. electronics, connectors, front panel, etc.) are installed to form the card assembly 212. The front edge 176 of the PCB 213 can define a front X-Z plane 260. The front panel 110 can be parallel to the front X-Z plane 260, but spaced away from the front plane 260. The front X-Z plane 260 is defined by the points of the PCB 213 that are farthest away from the rear edge 177 of the PCB 213. Therefore, notches at the front edge 176 of the PCB 213 for installing connectors along the front edge 176 may tend to meander the front edge profile, but the front X-Z plane 260 is defined by the points of the PCB 213 that are farthest away from the rear edge 177 (or farthest away from the rear X-Z plane 262).

Similarly, the rear X-Z plane 262 is defined by the points of the PCB 213 in the 6U P-XLe region 230 that are farthest away from the front edge 176 of the PCB 213. Therefore, notches at the rear edge 177 of the PCB 213 for installing connectors along the rear edge 177 may tend to meander the rear edge profile, but the rear X-Z plane 262 is defined by the points of the PCB 213 in the 6U P-XLe region 230 that are farthest away from the front edge 176 (or farthest away from the front X-Z plane 260).

Similarly, the rear X-Z plane 264 is defined by the points of the PCB 213 in the 3U PXI region 210 that are farthest away from the front edge 176 of the PCB 213. Therefore, notches at the rear edge 178 of the PCB 213 for installing connectors along the rear edge 178 may tend to meander the rear edge profile, but the rear X-Z plane 264 is defined by the points of the PCB 213 in the 3U PXI region 210 that are farthest away from the front edge 176 (or farthest away from the front X-Z plane 260).

The rear X-Z plane 266 is defined by the rear edge 156, which, in this embodiment, is positioned away from the rear edge 178 toward the front edge 176 by a distance L4. The edge 156 forms a notch in the PCB 213 between the 6U P-XLe region 230 and the 3U region 210. The edges 158 and 152 can form sides of the notch, with the edge 156 forming a bottom of the notch. The depth of the notch is represented by the distance L4. The length of the edge 156 can form the width of the notch, with the width being a length L7. The size of the notch can be adjusted as needed to accommodate varying structures in the various configurations of the chassis 101.

The height of the 3U PXI region 210 is measured in the Z-direction along the front X-Z plane 260 and is indicated by the height L6. The height of the 6U P-XLe region 230 is measured in the Z-direction along the front X-Z plane 260 and is indicated by the height L5. The combination of the height L5 and the height L6 provides the overall height of the PCB 213. The combination of the height L5 and the height L6 is substantially equal to a height of a standard 6U PXI™ Express PCB assembly. The height L5 can be at least 1.1 times, or at least 1.2 times, or at least 1.3 times greater than the height L6. The height L6 can be substantially equal to the height of a standard 3U PXI™ Express PCB assembly.

A distance between the front X-Z plane 260 and the rear X-Z plane 262 is defined as length L1. A distance between the front X-Z plane 260 and the rear X-Z plane 264 is defined as length L2. A distance between the rear X-Z plane 264 and the rear X-Z plane 262 is defined as length L3. The length L1 can be greater than the length L2. The length L1 can be at least 10%, or at least 15%, or at least 20%, or at least 25%, or at least 30%, or at least 35%, or at least 40%, or at least 45%, or at least 50%, or at least 55%, or at least 60%, or at least 65%, or at least 70% greater than second length L2.

FIG. 9B is a representative side view of a 6U P-XLe System card 200 as described above regarding FIG. 9A, with an expansion card assembly 206 included in the space between the 3U PXI region 210 and the rear of the chassis 101, according to one or more example embodiments. The expansion card 206 can include an expansion region 240 that contains the expansion card 206 circuitry. The expansion card 206 can be installed from the rear of the chassis 101 and positioned in the same Y-Z plane of the 6U P-XLe System card 200. Card guide 194 can be used to guide the expansion card 206 into the card slot and to align connectors 246 with connectors on the 3U backplane 102, or alternatively to align with connectors on a backplane 103. As stated above, the backplane 103 can also be used to distribute power within the chassis 101. Optional rear I/O connectors 242 can be installed at the rear edge of the expansion card 206 to provide interfaces between the expansion card 206 and equipment that is external to the card 206. These connectors 242 can include various types of connectors for transmitting various types of signals (e.g. single-ended signals, twisted pair signals, controlled impedance signals transmitted over coax, optical waveguides, optical signals, etc.).

FIG. 9C is a representative side view of a 6U P-XLe System card 200, according to one or more example embodiments. The card 200 includes two separate cards 212 and 202. The card 212 can include a front panel 110a with optional connectors 122a (not shown) that can extend through the front panel 110a. The card 202 can include a front panel 110b with optional connectors 122b (not shown) that can extend through the front panel 110b. The extraction mechanism 108 can be used to assist an operator in removing and/or inserting the card 212 into the chassis 101. The extraction mechanism 106 can be used to assist an operator in removing and/or inserting the card 202 into the chassis 101. The card 212 can include a top edge 150 that can engage the top card guides 140 when the card is installed in the chassis 101. The card 212 can include a front portion with a bottom edge that can engage the card guide 190 (positioned between the cards 212 and 202) when the card is installed in the chassis 101. The card 212 can include a rear portion with a bottom edge 152 that can engage the intermediate card guides 142 (FIG. 8) when the card is installed in the chassis 101. A notch 156 can be formed in the card 212 to provide clearance from structures in the chassis 101 that may be used to support the backplane 102.

The card 202 can include a bottom edge 154 that can engage the bottom card guides 144 when the card is installed in the chassis 101. The card 202 can include a top edge that can engage the card guide 190 (positioned between the cards 212 and 202) when the card is installed in the chassis 101.

The card 212 can include the 6U P-XLe region 230 that contains circuitry in addition to the circuitry contained in the card 202 that includes the 3U PXI region 210. The 3U PXI region 210 can contain circuitry that complies with the 3U PXI™ standards as well as additional circuitry if needed.

The standard 3U connectors that mate with the backplane 102 connectors 146 when the card 200 is installed in the chassis 101 can be contained within the 3U PXI region 210 to interface with the backplane 102. Optional I/O connectors 122c can be installed on edge 177 of the card 212. These connectors 122c can plug into an optional backplane 184 or they can connect directly to external connections, without the backplane 184 being installed. These optional I/O connectors 122c may not be installed at all, depending upon the I/O requirements of the system 100.

The card assembly 212 that can include a PCB 213, which can be seen as the foundational structure onto which remaining components of the card assembly 212 (e.g. electronics, connectors, front panel, etc.) can be installed to form the card assembly 212. The front edge 176b of the PCB 213 can define a front X-Z plane 260. The front panel 110a can be parallel to the front X-Z plane 260a, but spaced away from the front X-Z plane 260a. The front X-Z plane 260a is defined by the points of the PCB 213 that are farthest away from the rear edge 177 of the PCB 213. Therefore, notches at the front edge 176b of the PCB 213 for installing connectors along the front edge 176b may tend to meander the front edge profile, but the front X-Z plane 260a is defined by the points of the PCB 213 that are farthest away from the rear edge 177 (or farthest away from the rear X-Z plane 262).

Similarly, the rear X-Z plane 262 is defined by the points of the PCB 213 in the 6U P-XLe region 230 that are farthest away from the front edge 176a of the PCB 213. Therefore, notches at the rear edge 177 of the PCB 213 for installing connectors along the rear edge 177 may tend to meander the rear edge profile, but the rear X-Z plane 262 is defined by the points of the PCB 213 in the 6U P-XLe region 230 that are farthest away from the front edge 176a (or farthest away from the front X-Z plane 260a).

The front edge 176b of the PCB 203 can define a front X-Z plane 260b. The front panel 110b can be parallel to the front X-Z plane 260b, but spaced away from the front X-Z plane 260b. The front X-Z plane 260b is defined by the points of the PCB 203 that are farthest away from the rear edge 178 of the PCB 203. Therefore, notches at the front edge 176b of the PCB 203 for installing connectors along the front edge 176b may tend to meander the front edge profile, but the front X-Z plane 260b is defined by the points of the PCB 203 that are farthest away from the rear edge 178 (or farthest away from the rear X-Z plane 264). The front X-Z planes 260a, 260b can be aligned with each other forming a single front X-Z plane 260.

Similarly, the rear X-Z plane 264 is defined by the points of the PCB 203 in the 3U PXI region 210 that are farthest away from the front edge 176b of the PCB 203. Therefore, notches at the rear edge 178 of the PCB 203 for installing connectors along the rear edge 178 may tend to meander the rear edge profile, but the rear X-Z plane 264 is defined by the points of the PCB 203 in the 3U PXI region 210 that are farthest away from the front edge 176b (or farthest away from the front X-Z plane 260b).

The rear X-Z plane 266 is defined by the rear edge 156, which, in this embodiment, is positioned away from the rear edge 177 toward the front edge 176a by a distance L4+L3. The edges 156 and 152 form a notch in bottom of the PCB 213. The depth of the notch is represented by the distance L4+L3. The length of the edge 156 can form the width of the notch, with the width being a length L7. The size of the notch can be adjusted as needed to accommodate varying structures in the various configurations of the chassis 101.

The height of the 3U PXI region 210 is measured in the Z-direction along the front X-Z plane 260b and is indicated by the height L6. The height of the 6U P-XLe region 230 is measured in the Z-direction along the front X-Z plane 260a and is indicated by the height L5. The height L6 can be the height of the PCB 203, with the height L5 being height of the PCB 213 (including the card guide 190 vertical spacing). The combination of the height L5 and the height L6 is substantially equal to a height of a standard 6U PXI™ Express PCB assembly. The height L5 can be at least 1.1 times, or at least 1.2 times, or at least 1.3 times greater than the height L6. The height L6 can be substantially equal to the height of a standard 3U PXI™ Express PCB assembly.

A distance between the front X-Z plane 260a and the rear X-Z plane 262 is defined as length L1. A distance between the front X-Z plane 260b and the rear X-Z plane 264 is defined as length L2. A distance between the rear X-Z plane 264 and the rear X-Z plane 262 is defined as length L3. The length L1 can be greater than the length L2. The length L1 can be at least 10%, or at least 15%, or at least 20%, or at least 25%, or at least 30%, or at least 35%, or at least 40%, or at least 45%, or at least 50%, or at least 55%, or at least 60%, or at least 65%, or at least 70% greater than second length L2.

FIG. 9D is a representative side view of a 6U P-XLe System card 200 as described above regarding FIG. 9C, with an expansion card assembly 206 included in the space between the 3U PXI region 210 and the rear of the chassis 101, according to one or more example embodiments. The expansion card 206 can include an expansion region 240 that contains the expansion card 206 circuitry. The expansion card 206 can be installed from the rear of the chassis 101 and positioned in the same Y-Z plane of the 6U P-XLe System card 200, which can include the PCBs 203, 213. Card guides (not shown) can be used to guide the expansion card 206 into the card slot and to align connectors 246 with connectors on the 3U backplane 102, or alternatively to align with connectors on a backplane 103. As stated above, the backplane 103 can also be used to distribute power within the chassis 101. Optional rear I/O connectors 242 can be installed at the rear edge of the expansion card 206 to provide interfaces between the expansion card 206 and equipment that is external to the card 206. These connectors 242 can include various types of connectors for transmitting various types of signals (e.g. single-ended signals, twisted pair signals, controlled impedance signals transmitted over coax, optical waveguides, optical signals, etc.).

FIG. 9E is a representative side view of a 6U P-XLe System card 200 with the 3U PXI region 210 justified to the rear of the card 200, according to one or more example embodiments. In this example, the 6U P-XLe System card 200 is a generally rectangle card assembly, with an L-shaped 6U P-XLe region 230 that borders the 3U PXI region 210 along lines 164, 168.

The card 200 can include a front panel 110 with optional connectors 122a, 122b (not shown) that can extend through the front panel 110. One or both of the extraction mechanisms 108, 106 can be used to assist an operator in removing and/or inserting the card 200 into the chassis 101. The P-XLe card 200 can include a top edge 150 that can engage the top card guides 140 when the card is installed in the chassis 101. The P-XLe card 200 can include a bottom edge 154 that can engage bottom card guides (e.g. extended card guides 144) when the card is installed in a compatible chassis 101. The 6U P-XLe region 230 contains circuitry in addition to the circuitry contained in the 3U PXI region 210. The 3U PXI region 210 can contain circuitry that complies with the 3U PXI™ standards as well as additional circuitry if needed. This 3U PXI™ compliant circuitry can be contained wholly within the 3U PXI region 210, or partially contained in the 6U P-XLe region 230 and partially contained in the 3U PXI region 210. It is not a requirement that the 3U PXI™ compliant circuitry be contained only within the 3U PXI region 210, even though it may be desirable to do so.

The standard 3U connectors (e.g. XP1, XJ2-4 that mate with the backplane 102 connectors 146 when the card 200 is installed in the chassis 101) can be contained within the 3U PXI region 210 to interface with the backplane 184. Optional I/O connectors 122c can be installed on edge 177 of the card 200. These connectors 122c can plug into the backplane 184 or they can connect directly to external connections, when the backplane 184 does not extend above the 3U PXI region 210. These optional I/O connectors 122c may not be installed at all, depending upon the I/O requirements of the system 100. If the backplane 184 extends to the 6U P-XLe region 230, the connectors 122c can be configured to couple to backplane connectors 186 on the backplane 184. If additional external I/O are desired, then the backplane 184 can be a double-sided backplane with connectors 186 on one side and additional optional I/O connectors 122c on the other side. There can also be additional I/O connectors on the other side of the backplane 184 from the connectors 146.

The P-XLe card 200 can be a card assembly 212 that can include a PCB 213. The PCB 213 can be seen as the foundational structure onto which remaining components of the card assembly 212 (e.g. electronics, connectors, front panel, etc.) are installed to form the card assembly 212. The front edge 176 of the PCB 213 can define a front X-Z plane 260. The front panel 110 can be parallel to the front X-Z plane 260, but spaced away from the front plane 260. The front X-Z plane 260 is defined by the points of the PCB 213 that are farthest away from the rear edge 177 of the PCB 213. Therefore, notches at the front edge 176 of the PCB 213 for installing connectors along the front edge 176 may tend to meander the front edge profile, but the front X-Z plane 260 is defined by the points of the PCB 213 that are farthest away from the rear edge 177 (or farthest away from the rear X-Z plane 262).

Similarly, the rear X-Z plane 262 is defined by the points of the PCB 213 that are farthest away from the front edge 176 of the PCB 213. Therefore, notches at the rear edge 177 of the PCB 213 for installing connectors along the rear edge 177 may tend to meander the rear edge profile, but the rear X-Z plane 262 is defined by the points of the PCB 213 that are farthest away from the front edge 176 (or farthest away from the front X-Z plane 260).

A rear X-Z plane 264 can be defined by the boundary line 168 that delineates an end of the 3U PXI region 210 and a beginning of the 6U P-XLe region 230. The 3U PXI region 210 is bounded by the horizontal (Y-direction) line 164 and the vertical (Z-direction) line 168. The height of the 3U PXI region 210 is measured in the Z-direction along the rear X-Z plane 264 and is indicated by the height L6. The height of the 6U P-XLe region 230 is measured in the Z-direction along the rear X-Z plane 264 and is indicated by the height L5. The combination of the height L5 and the height L6 provides the overall height of the PCB 213. The combination of the height L5 and the height L6 is substantially equal to a height of a standard 6U PXI™ Express PCB assembly. The height L5 can be at least 1.1 times, or at least 1.2 times, or at least 1.3 times greater than the height L6. The height L6 can be substantially equal to the height of a standard 3U PXI™ Express PCB assembly.

A distance between the front X-Z plane 260 and the rear X-Z plane 262 is defined as length L1. A distance between the front X-Z plane 260 and the rear X-Z plane 264 is defined as length L2. A distance between the rear X-Z plane 264 and the rear X-Z plane 262 is defined as length L3. The length L1 can be greater than the length L2. The length L1 can be at least 10%, or at least 15%, or at least 20%, or at least 25%, or at least 30%, or at least 35%, or at least 40%, or at least 45%, or at least 50%, or at least 55%, or at least 60%, or at least 65%, or at least 70% greater than second length L2.

In this configuration, the rear edge 177 of the 6U P-XLe region 230 (upper portion of the PCB 213) is in line with the rear edge of the 3U PXI region 210 (lower portion of the PCB 213). Therefore, the rear edge 177 that defines the rear X-Z plane 262 is common for both the 6U P-XLe region 230 and the 3U PXI region 210 of the PCB 213. Therefore, a backplane 184 (either single-sided or double sided) can be connected to both the 6U P-XLe region 230 and the 3U PXI region 210.

FIG. 9F is a representative side view of a 6U P-XLe System card 200, according to one or more example embodiments. The card 200 includes two separate cards 212 and 208. The card 212 can include a front panel 110 with optional connectors 122a, 122b (not shown) that can extend through the front panel 110. The extraction mechanisms 106, 108 can be used to assist an operator in removing and/or inserting the card 212 into the chassis 101. The card 212 can include a top edge 150 that can engage the top card guides 140 when the card is installed in the chassis 101. The card 212 can include a rear portion with a bottom edge 152 that can engage the card guide 190 (positioned between the cards 212 and 208) when the cards 212 and 208 are installed in the chassis 101. The card 212 can include a front portion with a bottom edge 154 that can engage the card guides 144 (FIG. 8) when the card is installed in the chassis 101. The card 208 can include a top edge 158 that can engage the card guide 190 (positioned between the cards 212 and 208) when the card 208 is installed in the chassis 101.

The card 212 can include the 6U P-XLe region 230 that contains circuitry in addition to the circuitry contained in the card 208 that includes the 3U PXI region 210. The 3U PXI region 210 can contain circuitry that complies with the 3U PXI™ standards as well as additional circuitry if needed.

The standard 3U connectors (e.g. XP1, XJ2-4 that mate with the backplane 184 connectors 146 when the card 208 is installed in the chassis 101) can be positioned at the rear edge 175 of the PCB 209. Optional I/O connectors 122c can be installed on edge 177 of the card 212. These connectors 122c can plug into an optional backplane 184 or they can connect directly to external connections, without the backplane 184 being installed. These optional I/O connectors 122c may not be installed at all, depending upon the I/O requirements of the system 100.

The card assembly 212 can include a PCB 213, which can be seen as the foundational structure onto which remaining components of the card assembly 212 (e.g. electronics, connectors, front panel, etc.) can be installed to form the card assembly 212. The front edge 176 of the PCB 213 can define a front X-Z plane 260. The front panel 110 can be parallel to the front X-Z plane 260, but spaced away from the front X-Z plane 260. The front X-Z plane 260 is defined by the points of the PCB 213 that are farthest away from the rear edge 177 of the PCB 213. Therefore, notches at the front edge 176 of the PCB 213 for installing connectors along the front edge 176 may tend to meander the front edge profile, but the front X-Z plane 260 is defined by the points of the PCB 213 that are farthest away from the rear edge 177 (or farthest away from the rear X-Z plane 262).

Similarly, the rear X-Z plane 262a is defined by the points of the PCB 213 in the 6U P-XLe region 230 that are farthest away from the front edge 176 of the PCB 213. Therefore, notches at the rear edge 177 of the PCB 213 for installing connectors along the rear edge 177 may tend to meander the rear edge profile, but the rear X-Z plane 262a is defined by the points of the PCB 213 in the 6U P-XLe region 230 that are farthest away from the front edge 176 (or farthest away from the front X-Z plane 260).

The rear X-Z plane 262b is defined by the points of the PCB 209 that are farthest away from the front edge 179 of the PCB 209. Therefore, notches at the rear edge 178 of the PCB 209 for installing connectors along the rear edge 178 may tend to meander the rear edge profile, but the rear X-Z plane 262b is defined by the points of the PCB 209 that are farthest away from the front edge 179 (or farthest away from the front X-Z plane 266).

The front X-Z plane 266 is defined by the front edge 179 of PCB 209, which, in this embodiment, is positioned away from the rear edge 175 toward the front panel 110b by a distance of L3 minus L8.

The rear X-Z plane 264 is defined by the rear edge 156, which, in this embodiment, is positioned away from the rear edge 177 toward the front edge 176 by a distance L3 and away from the front edge 176 by a distance L2. The length of the edge 156 can be larger than the height L6 of the 3U PCB 209, which can be a result of the clearance needed between the edge 152 of PCB 213 and the edge 159 of PCB 209 to accommodate the card guide 190. The front edge 179 of the PCB 209 can be spaced away (length L8) from the rear edge 156 of the PCB 213 to allow space for a card guide 192 that helps align the PCB 213 with the PCB 209 when the card 212 is installed in the chassis 101. This configuration can be somewhat cumbersome for system maintenance, since the card 212 must be removed to remove/replace the card 208. However, this configuration does provide the upgradability from a VXI instrumentation system to a P-XLe instrumentation system, which can utilize the plethora of existing 3U PXI™ Express cards.

The height of the 3U PXI PCB 209 is measured in the Z-direction along the front X-Z plane 266 and is indicated by the height L6. The height of the 6U P-XLe region 230 is measured in the Z-direction along the front X-Z plane 260 and is indicated by the height L5. The height L6 can be the height of the PCB 209, with the height L5+L6 being height of the PCB 213 (including the card guide 190 vertical spacing). The combination of the height L5 and the height L6 is substantially equal to a height of a standard 6U PXI™ Express PCB assembly. The height L5 can be at least 1.1 times, or at least 1.2 times, or at least 1.3 times greater than the height L6. The height L6 can be substantially equal to the height of a standard 3U PXI™ Express PCB assembly.

A distance between the front X-Z plane 260 and the rear X-Z plane 262a is defined as length L1. A distance between the front X-Z plane 260 and the rear X-Z plane 264 is defined as length L2. A distance between the rear X-Z plane 264 and the rear X-Z plane 262 is defined as length L3. The length L1 can be greater than the length L2. The length L1 can be at least 10%, or at least 15%, or at least 20%, or at least 25%, or at least 30%, or at least 35%, or at least 40%, or at least 45%, or at least 50%, or at least 55%, or at least 60%, or at least 65%, or at least 70% greater than second length L2.

FIG. 9G is a representative side view of a 6U P-XLe System card 200, according to one or more example embodiments. The card 200 includes three separate cards 212, 208, and 214. The card 212 can include a front panel 110a with optional connectors 122a (not shown) that can extend through the front panel 110a. The card 214 can include a front panel 110b with optional connectors 122b (not shown) that can extend through the front panel 110b. The extraction mechanism 108 can be used to assist an operator in removing and/or inserting the card 212 into the chassis 101. The extraction mechanism 106 can be used to assist an operator in removing and/or inserting the cards 208 and 214 into the chassis 101. The card 212 can include a top edge 150 that can engage the top card guides 140 when the card is installed in the chassis 101. The card 212 can include a bottom edge 154 that can engage the card guide 190 (positioned between the card 212 and the cards 214, 208) when the card 212 is installed in the chassis 101. The card 208 can include a top edge 158 that can engage the card guide 190 (positioned between the card 212 and the cards 214, 208) when the card 208 is installed in the chassis 101. The card 214 can be an extender assembly that can extend the structure of the card 208 to the front panel 110b. The front edge 179 of the card 208 can be removably fixed to the rear edge 178 of the card 214. The resulting extended card assembly (card 214 attached to card 208) can be removed and replaced independent of the card 212.

The card 212 can include the 6U P-XLe region 230 that contains circuitry in addition to the circuitry contained in the card 208 that includes the 3U PXI region 210. The 3U PXI region 210 can contain circuitry that complies with the 3U PXI™ standards as well as additional circuitry, if needed.

The standard 3U connectors (e.g. XP1, XJ2-4 that mate with the backplane 184 connectors 146 when the card 208 is installed in the chassis 101) can be positioned at the rear edge 175 of the PCB 209. Optional I/O connectors 122c can be installed on edge 177 of the card 212. These connectors 122c can plug into an optional backplane 184 or they can connect directly to external connections, without the backplane 184 being installed. These optional I/O connectors 122c may not be installed at all, depending upon the I/O requirements of the system 100.

The card assembly 212 can include a PCB 213, which can be seen as the foundational structure onto which remaining components of the card assembly 212 (e.g. electronics, connectors, front panel, etc.) can be installed to form the card assembly 212. The front edge 176 of the PCB 213 can define a front X-Z plane 260. The front panel 110 can be parallel to the front X-Z plane 260, but spaced away from the front X-Z plane 260. The front X-Z plane 260 is defined by the points of the PCB 213 that are farthest away from the rear edge 177 of the PCB 213. Therefore, notches at the front edge 176 of the PCB 213 for installing connectors along the front edge 176 may tend to meander the front edge profile, but the front X-Z plane 260 is defined by the points of the PCB 213 that are farthest away from the rear edge 177 (or farthest away from the rear X-Z plane 262a).

Similarly, the rear X-Z plane 262a is defined by the points of the PCB 213 in the 6U P-XLe region 230 that are farthest away from the front edge 176 of the PCB 213. Therefore, notches at the rear edge 177 of the PCB 213 for installing connectors along the rear edge 177 may tend to meander the rear edge profile, but the rear X-Z plane 262a is defined by the points of the PCB 213 in the 6U P-XLe region 230 that are farthest away from the front edge 176 (or farthest away from the front X-Z plane 260).

The rear X-Z plane 262b is defined by the points of the PCB 209 that are farthest away from the front edge 179 of the PCB 209. Therefore, notches at the rear edge 178 of the PCB 209 for installing connectors along the rear edge 178 may tend to meander the rear edge profile, but the rear X-Z plane 262b is defined by the points of the PCB 209 that are farthest away from the front edge 179 (or farthest away from the front X-Z plane 266).

The front X-Z plane 266 is defined by the front edge 179 of PCB 209, which, in this embodiment, is positioned away from the rear edge 175 toward the front panel 110b by a distance of L3 minus L8.

The rear X-Z plane 264 is defined by the rear edge 178, which, in this embodiment, is positioned away from the rear edge 177 toward the front edge 176 by a distance L3 and away from the front edge 176 by a distance L2. The length of the edge 178 can be the height L6 of the 3U PCB 209. Clearance may be needed between the edge 154 of PCB 213 and the edge 158 of PCB 209 to accommodate the card guide 190. The front edge 179 of the PCB 209 can be spaced away (length L8) from the rear edge 178 of the card 214 to allow space for a card guide 192 that helps align the card 214 with the PCB 209 when the card 214 is installed in the chassis 101. This configuration provides upgradability from a VXI instrumentation system to a P-XLe instrumentation system, which can utilize the plethora of existing 3U PXI™ Express cards.

The height of the 3U PXI PCB 209 is measured in the Z-direction along the front X-Z plane 266 and is indicated by the height L6. The height of the 6U P-XLe region 230 is measured in the Z-direction along the front X-Z plane 260 and is indicated by the height L5. The height L5 includes the clearance needed for the card guides 190. The height L6 can be the height in the Z-direction of the extension card 214. The height L6 can be the height of the PCB 209, with the height L5+L6 being height of the PCB 213 (including the card guide 190 vertical spacing). The combination of the height L5 and the height L6 is substantially equal to a height of a standard 6U PXI™ Express PCB assembly. The height L5 can be at least 1.1 times, or at least 1.2 times, or at least 1.3 times greater than the height L6. The height L6 can be substantially equal to the height of a standard 3U PXI™ Express PCB assembly.

A distance between the front X-Z plane 260 and the rear X-Z plane 262a is defined as length L1. A distance between the front X-Z plane 260 and the rear X-Z plane 264 is defined as length L2. A distance between the rear X-Z plane 264 and the rear X-Z plane 262a is defined as length L3. The distance between the front X-Z plane 266 of PCB 209 and the rear X-Z plane 264 is L8, which can be seen as a gap needed for clearance for a card guide 192 or a bracket for attaching the card 214 to the car 208. The length L1 can be greater than the length L2. The length L1 can be at least 10%, or at least 15%, or at least 20%, or at least 25%, or at least 30%, or at least 35%, or at least 40%, or at least 45%, or at least 50%, or at least 55%, or at least 60%, or at least 65%, or at least 70% greater than second length L2.

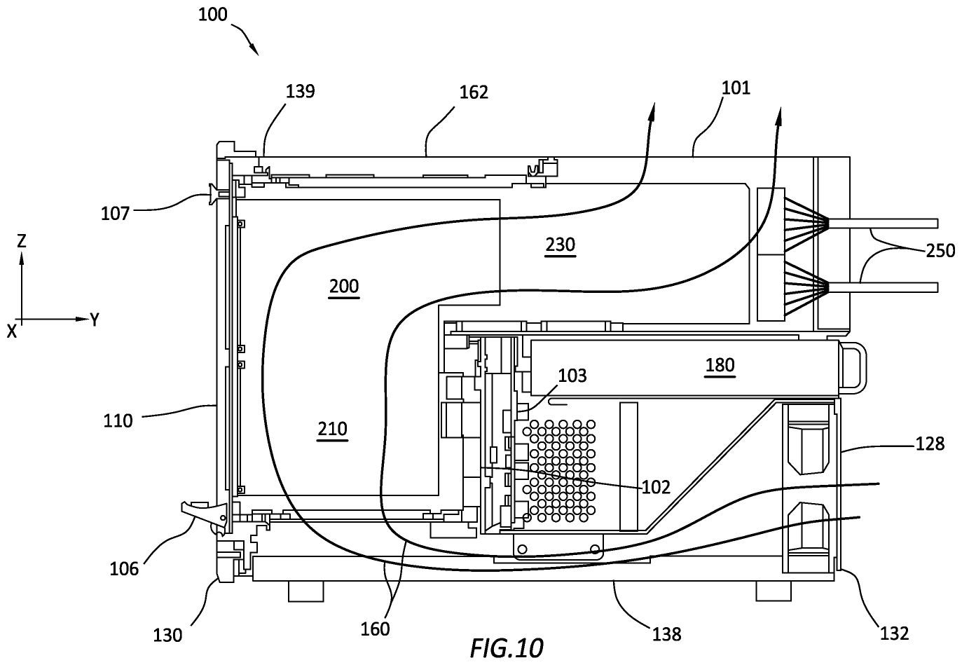

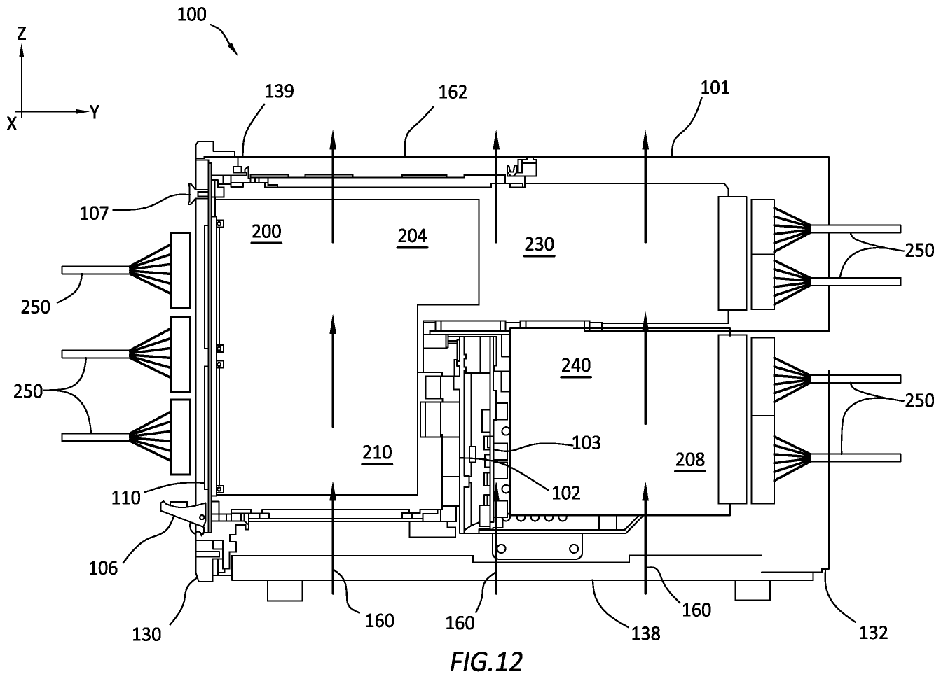

FIGS. 10 and 12 are representative cross-sectional side views of a system chassis 101 showing possible air flow options through the chassis 101. The one or more fans 128 can be used to draw air in from an external environment and force the air through the chassis 101. The chassis can direct the air flow as shown by arrows 160 in FIG. 10, where the air flow 160 passes under the backplanes 102, 103, travels up across electronics in the 3U PXI™ region 210, then across electronics in the 6U P-XLe region 230 to exit the chassis through the top 139 proximate the rear 132 of the chassis 101. A bulkhead 162 can be used to direct the air flow 160 toward the rear 132 of the chassis 101.

The chassis 101 can also direct the air flow as shown by arrows 160 in FIG. 11, where the air flow 160 passes under the backplanes 102, 103, travels up across electronics in the 3U PXI™ region 210, then across electronics in the 6U P-XLe region 230 to exit the chassis through the rear 132 of the chassis 101. A bulkhead 162 can be used to direct the air flow toward the rear 132 of the chassis 101. Also, one or more optional exhaust fans 148 can be used to assist in pulling the exhaust air out the rear 132 of the chassis 101. However, it should be understood that other modifications to air flow 160 can be made without departing from the principles of this disclosure.

The chassis 101 that can also direct the air flow as shown by arrows 160 in FIG. 12, where the air flow 160 passes into the chassis 101 through the bottom 138, passes over the various electronics in the 3U PXI™ region 210, the 6U P-XLe region 230, and the expansion region 240 to exit the chassis through the top 139 of the chassis 101. In this configuration, conditioned air can be received from a raised floor plenum on which a rack assembly rests, into a bottom of the rack assembly, through one or more chassis in the rack assembly and exhaust out a top of the rack assembly. Care should be taken to ensure that the electronics in the top chassis 101 in the rack assembly remains within working temperature ranges during operation due to the continually increasing temperature of the air as it flows up through the rack assembly.

Additionally, plenums can be installed in the rack assembly to provide inlet air to the bottom 138 of each chassis and exhaust the exhaust air received out the top 139 of the chassis 101 such that the exhausted air does not enter a subsequent chassis 101.

As mentioned above, fan trays (e.g. 1U high trays with a plurality of horizontally mounted fans) can be used in a rack assembly to force air 160 through the bottom 138 of the chassis 101, as well as optionally pulling air out the top 139 of the chassis. These fan trays can also include heat exchangers to extract the heat from the air exhausted from the chassis 101 before the air enters the next chassis 101 in the rack assembly.

It should be understood, that the air flow 160 shown in FIGS. 10-12 can also be reversed to flow in the opposite direction from what is shown, in keeping with the principles of this disclosure.

Although various embodiments have been shown and described, the disclosure is not limited to such embodiments and will be understood to include all modifications and variations as would be apparent to one skilled in the art. Therefore, it should be understood that the disclosure is not intended to be limited to the particular forms disclosed; rather, the intention is to cover all modifications, equivalents, and alternatives falling within the spirit and scope of the disclosure as defined by the appended claims.

### Various Embodiments

Embodiment 1. A printed circuit board (PCB) assembly comprising:

a first region comprising:
a first height L5,
a front edge defining a front plane, and
a first rear edge defining a first rear plane; and

a second region comprising:
a second height L6,
the front plane including a front edge of the second region, and
a second rear edge defining a second rear plane, wherein the first rear plane and the second rear plane are parallel to each other and are spaced apart from each other.

Embodiment 2. The assembly of embodiment 1, further comprising a distance between the front plane and the first rear plane defining a first length L1, and a distance between the front plane and the second rear plane defining a second length L2, wherein the first length L1 is greater than the second length L2.

Embodiment 3. The assembly of embodiment 2, wherein the first length L1 is at least 10% greater than second length L2.

Embodiment 4. The assembly of embodiment 2, wherein the first length L1 is at least 10%, or at least 15%, or at least 20%, or at least 25%, or at least 30%, or at least 35%, or at least 40%, or at least 45%, or at least 50%, or at least 55%, or at least 60%, or at least 65%, or at least 70% greater than second length L2.

Embodiment 5. The assembly of embodiment 2, further comprising a third rear edge defining a third rear plane, wherein the third rear plane is parallel to the second rear plane, and wherein the third rear plane is spaced toward the front plane by a distance L4 and forms a notch in the PCB assembly between the first and second regions.

Embodiment 6. The assembly of embodiment 1, wherein a connection port is coupled to the first rear edge, and wherein another connection port is coupled to the second rear edge.

Embodiment 7. The assembly of embodiment 1, wherein the first height L5 is at least 1.1 times greater than the second height L6.

Embodiment 8. The assembly of embodiment 7, wherein the second height L6 is substantially equal to a height of a standard 3U PXI™ Express PCB assembly.

Embodiment 9. The assembly of embodiment 8, wherein the combination of the first height L5 and the second height L6 is substantially equal to a height of a standard 6U PXI™ Express PCB assembly.

Embodiment 10. The assembly of embodiment 1, wherein the PCB assembly is configured to consume a total power that is greater than a maximum power rating for a standard 6U PXI™ Express PCB assembly.

Embodiment 11. An instrumentation system for configurable test solutions, the system comprising:

a chassis configured to receive a first card, with the first card being a printed circuit board (PCB) assembly;

the first card comprising:
a front edge forming a front plane,
a first rear edge forming a first rear plane, and
a second rear edge forming a second rear plane, with the first rear plane being spaced a greater distance away from the front plane than the second rear plane; and

the chassis comprising:
a plurality of card slots configured to receive the first card,
a 3U backplane configured to couple with the second rear edge of the card when the first card is installed in one of the plurality of card slots in the chassis.

Embodiment 12. The system of embodiment 11, wherein the first card is a printed circuit board (PCB) assembly of embodiment 1.

Embodiment 13. The system of embodiment 11, wherein the chassis is configured to receive a second card in another one of the plurality of card slots, and wherein the second card is configured to couple with the 3U backplane and communicate with the first card via the 3U backplane.

Embodiment 14. The system of embodiment 13, wherein the second card is a standard 3U PXI™ Express PCB assembly, and wherein the 3U backplane supports communication protocols for a standard 3U PXI™ Express backplane.

Embodiment 15. The system of embodiment 11, wherein the first rear edge is configured to couple to external cables at a rear of the chassis.

Embodiment 16. The system of embodiment 11, wherein the first card is configured for installation in the one of the plurality of card slots, and wherein the first card extends from the one of the plurality of card slots into an adjacent one of the plurality of card slots.

Embodiment 17. The system of embodiment 11, wherein the chassis is configured to supply a total power to at least one of the plurality of card slots, and wherein the total power is greater than 140 watts.

Embodiment 18. The system of embodiment 17, wherein the total power is at least 10%, or at least 20%, or at least 30%, or at least 40%, or at least 50%, or at least 60%, or at least 70%, or at least 80%, or at least 90%, or at least 100%, or at least 110%, or at least 120%, or at least 130%, or at least 140%, or at least 150%, or at least 160%, or at least 170%, or at least 180%, or at least 190%, or at least 200%, or at least 210%, or at least 220%, or at least 230%, or at least 240%, or at least 250%, or at least 260%, or at least 270%, or at least 280% greater than total power per card slot for a 6U PXI™ Express chassis.

Embodiment 19. The system of embodiment 11, wherein the chassis further comprises card guides for a first card slot of the plurality of card slots, wherein the card guides comprise a top card guide, a first bottom card guide, and a second bottom card guide, wherein the card guides for the first card slot are configured to guide the first card into the first card slot, wherein the top card guide engages a top edge of the first card and the first bottom card guide and the second bottom card guide are configured to engage separate bottom edge portions of the first card, with the first bottom card guide being a greater vertical distance from the top card guide than the second bottom card guide.

Embodiment 20. The system of embodiment 11, wherein the chassis further comprises a chassis height and a chassis width, wherein the chassis height is measured in a Z direction and the chassis height is substantially equal to a standard 6U PXI™ Express chassis height, and wherein the chassis width is measured in an X direction and the chassis width is substantially equal to a standard 6U PXI™ Express chassis width.

Embodiment 21. The system of embodiment 11, wherein the chassis comprises a power supply positioned within the chassis, wherein the power supply is positioned below a rear portion of the first card and behind a bottom portion of the first card.

Embodiment 22. The system of embodiment 21, wherein the chassis is configured to flow air across the first card to remove heat dissipated by the first card during operation of the first card.

Embodiment 23. The system of embodiment 22, wherein the air flow comprises intake of air from a bottom portion of a rear of the chassis, movement of the air toward a front of the chassis, movement of the air upward across a portion of the first card proximate the front of the chassis, movement of the air toward a top portion of the rear of the chassis, with air exhausting from the chassis at the top portion of the rear of the chassis.

Embodiment 24. The system of embodiment 22, wherein the air flow comprises intake of air from a bottom portion of a rear of the chassis, movement of the air toward a front of the chassis, movement of the air upward across a portion of the first card proximate the front of the chassis, movement of the air toward a top portion of the rear of the chassis, with air exhausting from the chassis proximate the rear of the chassis.

Embodiment 25. The system of embodiment 24, wherein the air exhausts from the chassis through a top portion of the chassis at the rear of the chassis, or wherein the air exhausts from the chassis through a top portion of the rear of the chassis.

Embodiment 26. The system of embodiment 24, wherein the air exhausts from the chassis through a top portion of the rear of the chassis, with fans positioned at the top portion of the rear of the chassis to assist in pulling the air from the chassis.

Embodiment 27. The system of embodiment 22, wherein the air flow comprises intake of air from a bottom of the chassis, movement of the air across the first card toward a top of the chassis, and exhausting the air through a top of the chassis.

Embodiment 28. The system of embodiment 11, wherein the chassis is configured to couple, via electrical connections, to one or more other chassis that are similar to the chassis.

Embodiment 29. The system of embodiment 11, wherein the chassis further comprises an expansion area for standard PXI Express controller cards.

While the present disclosure may be susceptible to various modifications and alternative forms, specific embodiments have been shown by way of example in the drawings and tables and have been described in detail herein. However, it should be understood that the embodiments are not intended to be limited to the particular forms disclosed. Rather, the disclosure is to cover all modifications, equivalents, and alternatives falling within the spirit and scope of the disclosure as defined by the following appended claims. Further, although individual embodiments are discussed herein, the disclosure is intended to cover all combinations of these embodiments.

1. A printed circuit board (PCB) assembly comprising:
a first region comprising:
a first height L5,
a front edge defining a front plane, and
a first rear edge defining a first rear plane; and
a second region comprising:
a second height L6,
the front plane including a front edge of the second region, and
a second rear edge defining a second rear plane, wherein the first rear plane and the second rear plane are parallel to each other and are spaced apart from each other.

2. The assembly of claim 1, further comprising a distance between the front plane and the first rear plane defining a first length L1, and a distance between the front plane and the second rear plane defining a second length L2, wherein the first length L1 is greater than the second length L2.

3. The assembly of claim 2, wherein the first length L1 is at least 10% greater than second length L2.

4. The assembly of claim 2, wherein the first length L1 is at least 10%, or at least 15%, or at least 20%, or at least 25%, or at least 30%, or at least 35%, or at least 40%, or at least 45%, or at least 50%, or at least 55%, or at least 60%, or at least 65%, or at least 70% greater than second length L2.

5. The assembly of claim 2, further comprising a third rear edge defining a third rear plane, wherein the third rear plane is parallel to the second rear plane, and wherein the third rear plane is spaced toward the front plane by a distance L4 and forms a notch in the PCB assembly between the first and second regions.

6. The assembly of claim 1, wherein a connection port is coupled to the first rear edge, and wherein another connection port is coupled to the second rear edge.

7. The assembly of claim 1, wherein the first height L5 is at least 1.1 times greater than the second height L6.

8. The assembly of claim 7, wherein the second height L6 is substantially equal to a height of a standard 3U PXI™ Express PCB assembly.

9. The assembly of claim 8, wherein the combination of the first height L5 and the second height L6 is substantially equal to a height of a standard 6U PXI™ Express PCB assembly.

10. The assembly of claim 1, wherein the PCB assembly is configured to consume a total power that is greater than a maximum power rating for a standard 6U PXI™ Express PCB assembly.

11. An instrumentation system for configurable test solutions, the system comprising:
a chassis configured to receive a first card, with the first card being a printed circuit board (PCB) assembly;
the first card comprising:
a front edge forming a front plane,
a first rear edge forming a first rear plane, and
a second rear edge forming a second rear plane, with the first rear plane being spaced a greater distance away from the front plane than the second rear plane; and
the chassis comprising:
a plurality of card slots configured to receive the first card,
a 3U backplane configured to couple with the second rear edge of the card when the first card is installed in one of the plurality of card slots in the chassis.

12. The system of claim 11, wherein the first card is a printed circuit board (PCB) assembly of claim 1.

13. The system of claim 11, wherein the chassis is configured to receive a second card in another one of the plurality of card slots, and wherein the second card is configured to couple with the 3U backplane and communicate with the first card via the 3U backplane.

14. The system of claim 13, wherein the second card is a standard 3U PXI™ Express PCB assembly, and wherein the 3U backplane supports communication protocols for a standard 3U PXI™ Express backplane.

15. The system of claim 11, wherein the first rear edge is configured to couple to external cables at a rear of the chassis.

16. The system of claim 11, wherein the first card is configured for installation in the one of the plurality of card slots, and wherein the first card extends from the one of the plurality of card slots into an adjacent one of the plurality of card slots.

17. The system of claim 11, wherein the chassis is configured to supply a total power to at least one of the plurality of card slots, and wherein the total power is greater than 140 watts.

18. The system of claim 17, wherein the total power is at least 10%, or at least 20%, or at least 30%, or at least 40%, or at least 50%, or at least 60%, or at least 70%, or at least 80%, or at least 90%, or at least 100%, or at least 110%, or at least 120%, or at least 130%, or at least 140%, or at least 150%, or at least 160%, or at least 170%, or at least 180%, or at least 190%, or at least 200%, or at least 210%, or at least 220%, or at least 230%, or at least 240%, or at least 250%, or at least 260%, or at least 270%, or at least 280% greater than total power per card slot for a 6U PXI™ Express chassis.

19. The system of claim 11, wherein the chassis further comprises card guides for a first card slot of the plurality of card slots, wherein the card guides comprise a top card guide, a first bottom card guide, and a second bottom card guide, wherein the card guides for the first card slot are configured to guide the first card into the first card slot, wherein the top card guide engages a top edge of the first card and the first bottom card guide and the second bottom card guide are configured to engage separate bottom edge portions of the first card, with the first bottom card guide being a greater vertical distance from the top card guide than the second bottom card guide.

20. The system of claim 11, wherein the chassis further comprises a chassis height and a chassis width, wherein the chassis height is measured in a Z direction and the chassis height is substantially equal to a standard 6U PXI™ Express chassis height, and wherein the chassis width is measured in an X direction and the chassis width is substantially equal to a standard 6U PXI™ Express chassis width.
